(19) United States
(12) Patent Application Publication
(10) Pub. No.: US 2026/0304931 A1
(43) Pub. Date: Oct. 1, 2026

(54) SEMICONDUCTOR DEVICE AND MANUFACTURING METHOD THEREOF

(71) Applicant: Taiwan Semiconductor Manufacturing Company, Ltd., Hsin-Chu (TW)

(72) Inventors: Chiao-Ti Huang, Hsinchu (TW); Ka-Hing Fung, Zhudong Township (TW); Chi-An Wang, Hsinchu City (TW)

(21) Appl. No.: 19/288,846

(22) Filed: Aug. 1, 2025

Related U.S. Application Data
(60) Provisional application No. 63/781,657, filed on Apr. 1, 2025.

(51) Int. Cl. H10D 84/83; H10D 30/00; H10D 30/01; H10D 30/43; H10D 62/10; H10D 62/13; H10D 62/60; H10D 64/01; H10D 84/01

(52) U.S. Cl. CPC H10D 84/832; H10D 30/014; H10D 30/019; H10D 30/43; H10D 30/502; H10D 62/121; H10D 62/151; H10D 62/60; H10D 64/017; H10D 84/0142; H10D 84/8311

(57) ABSTRACT

A method includes providing a structure including a stack of alternating channel layers and interposers, an oxide layer over the stack, a dummy electrode over the oxide layer, a source/drain feature connected to the stack, a contact etch stop layer (CESL) along a top surface of the source/drain feature, an interlayer dielectric (ILD) layer over the CESL. The method further includes removing the dummy electrode to form an opening, forming a mask layer in the opening and over the CESL and the ILD layer, patterning the mask layer to remove the mask layer from the opening, performing a first etch process to remove a portion of the oxide layer, performing a second etch process to remove a portion of a topmost channel layer, removing a remainder of the mask layer, the interposers, and the oxide layer, and forming a gate structure in the opening and wrapping around lower channel layers.

### PRIORITY DATA

The present application claims the benefit of U.S. Provisional Application No. 63/781,657, filed Apr. 1, 2025, the entirety of which is herein incorporated by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, an IC may include multiple device regions, such as low speed regions and high speed regions. Reducing device capacitance of the low speed regions may be challenging as devices continue to scale down to multi-gate devices, such as FinFET, gate-all-around (GAA) devices including nanowire devices and nanosheet devices, and other types of multi-gate devices. Although existing structures and methods have been generally adequate for their intended purposes, they are not entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for fabricating a semiconductor structure according to various aspects of the present disclosure.

FIG. 2 illustrates a fragmentary top view of an exemplary structure at various fabrication stages associated with the method of FIG. 1 according to various aspects of the present disclosure.

FIGS. 3, 4, 5A, 5B, 6, 7, 8, 9, 10, 11, 12, 13A, 13B, 14A, 14B, 14C, 15, 16, 17, 18A, 18B, 19, 20, 21, 22, 23, 24, 25, 26, and 27 illustrate fragmentary cross-sectional views of an exemplary structure at various fabrication stages associated with the method of FIG. 1 according to various aspects of the present disclosure.

FIG. 28 illustrates a fragmentary top view of an exemplary structure fabricated by the method of FIG. 1 according to various aspects of the present disclosure.

FIGS. 29 and 30 illustrate fragmentary cross-sectional views of the exemplary structure taken along line D-D′ as in FIG. 28 according to various aspects of the present disclosure.

FIG. 31 illustrates a fragmentary top view of an exemplary structure fabricated by the method of FIG. 1 according to various aspects of the present disclosure.

FIG. 32 illustrates a fragmentary cross-sectional view of the exemplary structure taken along line E-E′ as in FIG. 31 according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Other ranges are possible as known by those skilled in the art and may be process dependent.

GAA transistors may also be referred to as nanosheet transistors or nanowire transistors. They can be either n-type or p-type. GAA transistors may have channel regions disposed in nanowire channel members, bar-shaped channel members, nanosheet channel members, nanostructure channel members, bridge-shaped channel members, and/or other suitable channel configurations. In some existing technologies, the formation of GAA transistors includes forming a number of channel layers interleaved by a number of sacrificial layers and performing a channel release process to selectively remove the sacrificial layers to release the channel layers as channel members. A semiconductor device may include multiple device regions, e.g., lower-power circuit region (i.e., lower-speed region or lower-capacitance region). The reduction of device capacitance may be limited by the widths of active regions. While existing techniques are generally adequate for their intended purposes, they are not satisfactory in all aspects.

The present disclosure is generally related to semiconductor structures and methods of fabricating same. More specifically, the present disclosure is related to GAA devices. In some embodiments, a method disclosed herein includes providing a structure. The structure includes a stack of alternating channel layers and interposers, an oxide layer disposed over the stack, and a dummy gate electrode disposed over the oxide layer. The interposers may include oxide layers or semiconductor sacrificial layers. The method further includes removing the dummy gate electrode to form a gate trench, and forming a patterned mask layer over the structure, thereby exposing at least a top portion of the oxide layer in the gate trench. The method further includes performing a first etching process to remove a top portion of the oxide layer, thereby exposing a middle portion of a topmost channel layer, and performing a second etching process to remove the exposed middle portion of the topmost channel layer. After the second etching process, a remainder of the topmost channel layer includes two end portions. The remaining full channel layers are then released, and a metal gate structure is formed in the gate trench to wrap around the remaining full channel layers. A portion of the metal gate structure is sandwiched between the two end portions of the topmost channel layer. By reducing the number of full channel layers (e.g., by removing the middle portion of the topmost channel layer), capacitance of the device may be reduced. Additional channel layers may be removed to further reduce the capacitance.

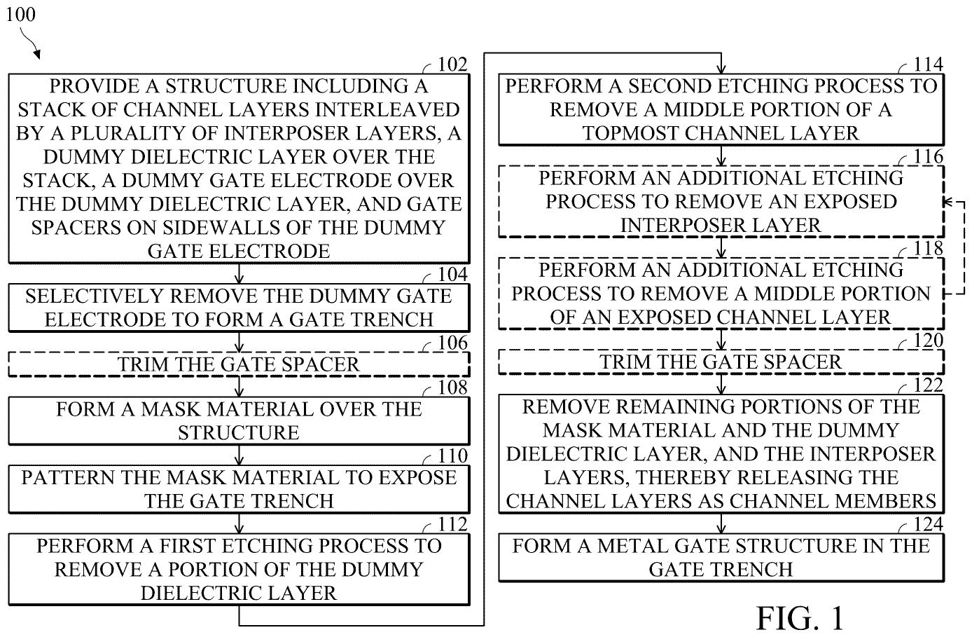

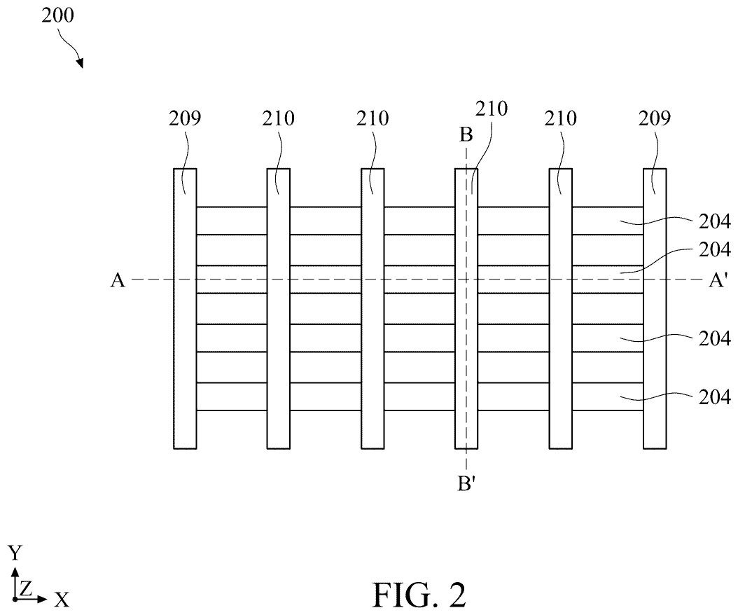

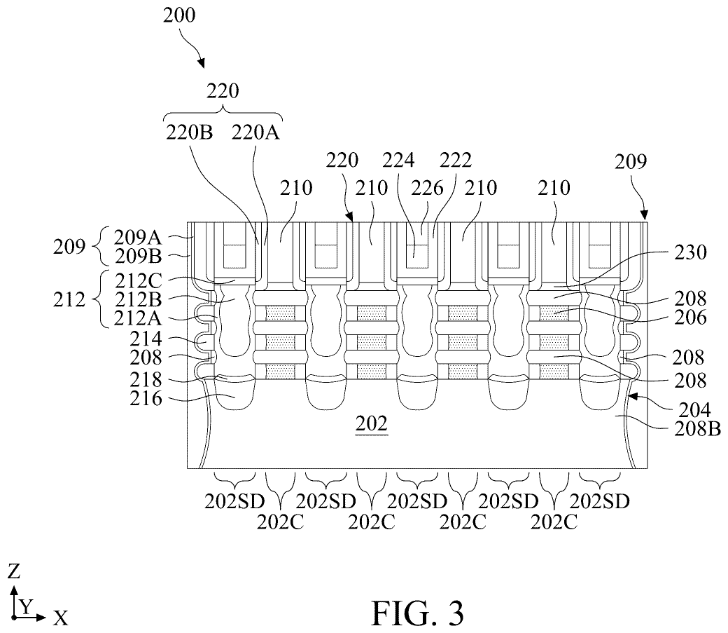

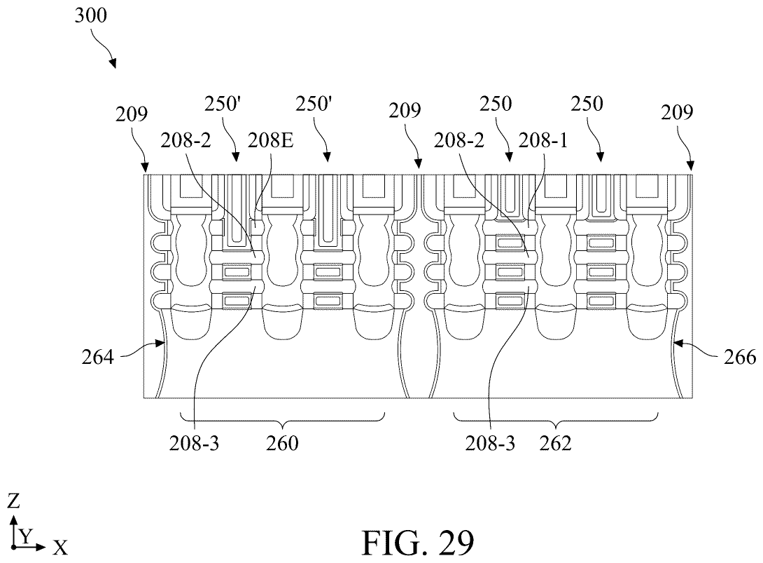

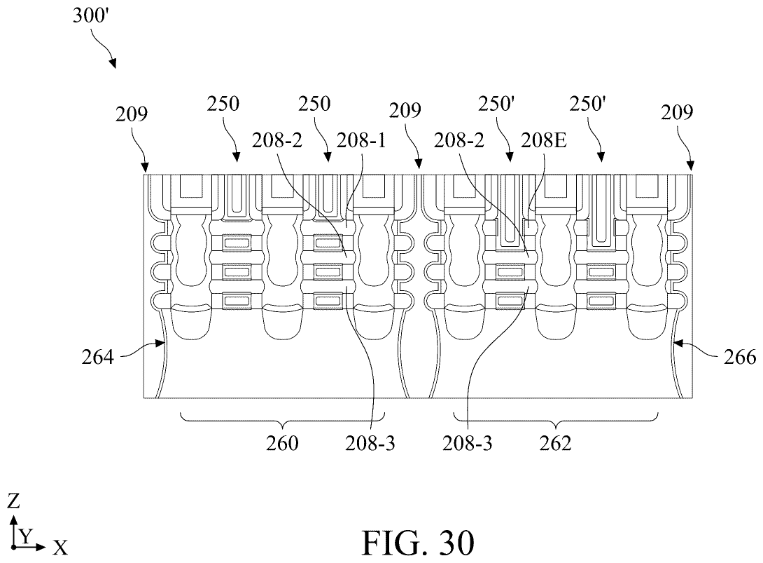

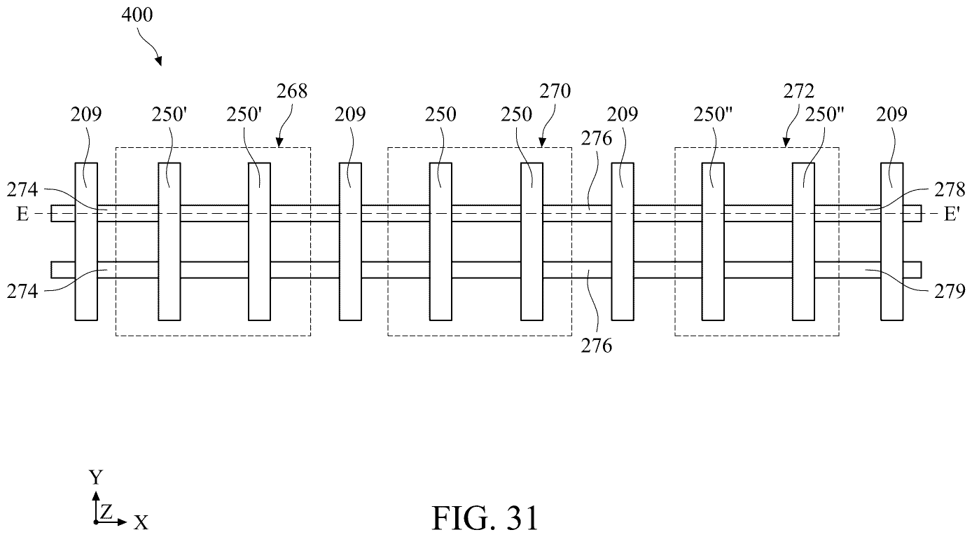

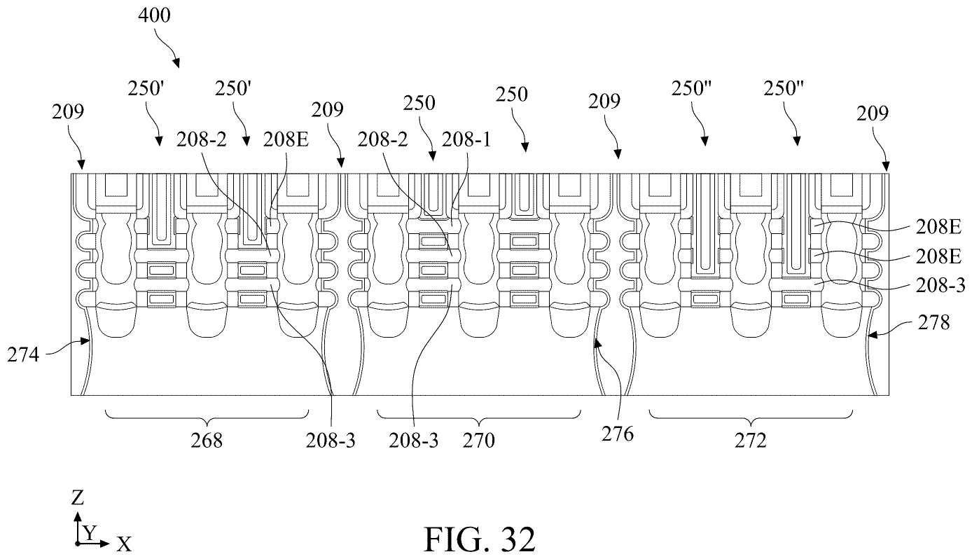

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2-27. FIG. 2 is a fragmentary top view of a structure 200 at different stages of fabrication according to embodiments of method 100 in FIG. 1. FIGS. 3-27 are fragmentary cross-sectional views of the structure 200 at different stages of fabrication according to embodiments of method 100 in FIG. 1. FIG. 28 is a fragmentary top view of a structure 300 or 300′ fabricated according to embodiments of method 100 in FIG. 1. FIGS. 29 and 30 are fragmentary cross-sectional views of the structure 300 and 300′, respectively, taken along line D-D′ as in FIG. 28. FIG. 31 is a fragmentary top view of a structure 400 fabricated according to embodiments of method 100 in FIG. 1. FIG. 32 is a fragmentary cross-sectional view of the structure 400 taken along line E-E′ as in FIG. 31. Method 100 is merely an example and is not intended to limit the present disclosure to what is explicitly illustrated in method 100. Additional steps can be provided before, during, and after method 100, and some steps described can be replaced, eliminated, or moved around for additional embodiments of method 100. Not all steps are described herein in detail for reasons of simplicity. Because the structure 200 (or 300, 300′, 400) will be fabricated into a semiconductor structure, the structure 200 (or 300, 300′, 400) may be referred to herein as a semiconductor structure 200 (or 300, 300′, 400) or a semiconductor device 200 (or 300, 300′, 400) as the context requires. For avoidance of doubts, the X, Y and Z directions in FIGS. 2-32 are perpendicular to one another and are used consistently throughout the present disclosure. Throughout the present disclosure, like reference numerals denote like features unless otherwise excepted. That is, material properties and comparisons thereof for various numbered elements described in association with a method or a figure should apply to the same numbered elements described in association with a different method or a different figure.

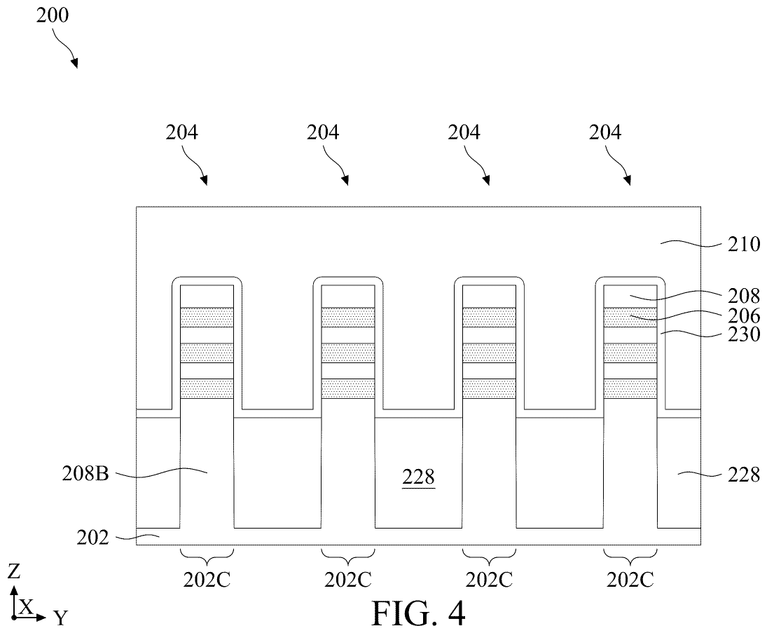

Referring now to FIGS. 1-4, method 100 includes a block 102 where a structure 200 is formed or provided. FIGS. 3 and 4 illustrate fragmentary cross-section views of the structure 200 taken along line A-A′ and line B-B′, respectively, as in FIG. 2.

As shown in FIG. 2, the structure 200 includes dummy gate electrodes 210 over active regions 204 (also referred to as fin-shaped structures 204) that include channel layers 208 interleaved by interposers 206. The active regions 204 extend lengthwise in the X direction. The dummy gate electrodes 210 extend lengthwise in the Y direction. In some embodiments, the structure 200 includes continuous poly on diffusion edge (CPODE) features 209 disposed on the edges of the active regions 204. The CPODE features 209 may extend lengthwise in the Y direction.

Referring to FIGS. 3 and 4, the active regions 204 are disposed over a substrate 202. The active region 204 includes channel regions 202C and source/drain regions 202SD. Source/drain regions 202SD of the active region 204 are recessed to form source/drain trenches and source/drain features 212 are formed in the source/drain trenches. Each of the source/drain features 212 interfaces end sidewalls of the channel layers 208 over the channel regions 202C. The interposers 206 are spaced apart from the source/drain features 212 by a plurality of inner spacer features 214. Each of the source/drain features 212 is vertically spaced apart from the substrate 202 by an interposing layer. In some embodiments, the interposing layer includes an undoped semiconductor feature 216, a bottom isolation layer 218, or both. A dummy gate electrode 210 is disposed over the channel layers 208 in each of the channel regions 202C. A gate spacer 220 is disposed along sidewalls of the dummy gate electrode 210. A contact etch stop layer (CESL) 222 is disposed along sidewalls of the gate spacer 220 and a top surface of the source/drain feature 212. An interlayer dielectric (ILD) layer 224 is disposed over the CESL 222. A dielectric cap layer 226 is disposed over the ILD layer 224. Sidewalls of the ILD layer 224 and the dielectric cap layer 226 are spaced apart from the gate spacer 220 by the CESL 222.

Reference is made to FIG. 4, which illustrates a dummy gate electrode 210 wrapping over four active regions 204. Each of the active regions 204 includes channel layers 208 stacked over a base fin 208B that is continuous from the substrate 202. Along the Y direction, the base fins 208B of the active regions 204 are separated by isolation features 228. The isolation feature 228 may also be referred to as a shallow trench isolation (STI) feature 228. A dummy dielectric layer 230 is deposited over the isolation feature 228 and the active region 204 before the deposition of the dummy gate electrode 210.

In one embodiment, the substrate 202 may be a silicon (Si) substrate. In some other embodiments, the substrate 202 may include other semiconductor materials such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure or a germanium-on-insulator (GeOI) structure. In some embodiments, the substrate 202 may include one or more well regions, such as n-type well regions doped with an n-type dopant (i.e., phosphorus (P) or arsenic (As)) or p-type well regions doped with a p-type dopant (i.e., boron (B)), for forming different types of devices. The doping the n-type wells and the p-type wells may be formed using ion implantation or thermal diffusion.

In some implementations, the channel layers 208 are formed of silicon (Si). The interposers 206 may include different compositions than the channel layers 208. In some embodiments, the interposers 206 include an oxide (e.g., silicon oxide) or a semiconductor material (e.g., silicon germanium (SiGe), germanium tin (GeSn), or a combination thereof). For embodiments where the interposers 206 include the oxide, the structure 200 may be formed by forming fin-shaped structures having the channel layers 206 and sacrificial layers (e.g., including SiGe) interleaving with the channel layers 206, forming the dummy gate electrodes 210, forming the source/drain trenches, replacing the sacrificial layers with the interposers 206, forming the source/drain features 212, and proceeding with further processes. It is noted that three (3) layers of the interposers 206 and three (3) layers of the channel layers 208 are alternately arranged as illustrated in FIGS. 3-4, which is for illustrative purposes only and not intended to be limiting beyond what is specifically recited in the claims. It can be appreciated that any number of layers may be formed. The number of layers depends on the desired number of channel layers for the semiconductor device 200. In some embodiments, the number of channel layers 208 is between 2 and 10.

The undoped semiconductor feature 216 may include undoped silicon or undoped silicon germanium. The bottom isolation layer 218 may include silicon nitride. Depending on the design, the source/drain features 212 may be either n-type or p-type. When they are n-type, they may include silicon (Si) doped with an n-type dopant such as phosphorus (P) or arsenic (As). When they are p-type, they may include silicon germanium (SiGe) and a p-type dopant, such as boron (B). The source/drain features 212 may include multiple epitaxial layers. In some embodiments represented in FIG. 3, each of the source/drain features 212 includes a first epitaxial layer 212A, a second epitaxial layer 212B over the first epitaxial layer 212A, and a third epitaxial layer 212C over the first epitaxial layer 212A and the second epitaxial layer 212B. In these embodiments, the first epitaxial layer 212A interfaces the end sidewalls of the channel layers 208, the second epitaxial layer 212B is highly doped to reduce contact resistance, and the third epitaxial layer 212C services to protect the first epitaxial layer 212A and the second epitaxial layer 212B. A concentration of a dopant, either n-type or p-type, in the second epitaxial layer 212B is higher than a concentration of the dopant in the first epitaxial layer 212A or in the third epitaxial layer 212C.

In some embodiments, the inner spacer features 214 include silicon nitride, silicon carbonitride, silicon oxycarbide, silicon oxycarbonitride, or silicon oxynitride. The gate spacer 220 may include silicon nitride, silicon carbonitride, silicon oxycarbide, silicon oxycarbonitride, or silicon oxynitride. In some embodiments, the gate spacer 220 may include more than one layer. For example, the gate spacer 220 may include a first layer 220A to interface the dummy gate electrode 210 and a second layer 220B spaced apart from the dummy gate electrode 210 by the first layer 220A. The first layer 220A and the second layer 220B may have different dielectric constants. In some instances, a dielectric constant of the first layer 220A is greater than a dielectric constant of the second layer 220B. The CESL 222 may include silicon nitride or silicon oxynitride. The interlayer dielectric (ILD) layer 224 may include tetraethylorthosilicate (TEOS) oxide, undoped silicate glass, or doped silicon oxide such as borophosphosilicate glass (BPSG), fused silica glass (FSG), phosphosilicate glass (PSG), boron doped silicon glass (BSG), and/or other suitable dielectric materials. The CESL 222 may have a smaller thickness (e.g., in the X direction or the Z direction) than the ILD layer 224. The dielectric cap layer 226 may share a similar composition with the CESL 222. The isolation feature 228 may include silicon oxide, silicon oxynitride, fluorine-doped silicate glass (FSG), a low-k dielectric, combinations thereof, and/or other suitable materials. In some embodiments, the isolation features 228 includes a liner disposed along sidewalls of the base fin 208B, a bulk layer embedded in the liner, and a protective layer over the liner and the bulk layer. The liner may include silicon oxide, silicon oxycarbide, silicon carbonitride, or a combination thereof. The liner may include multiple sublayers with different compositions. The protective layer may include nitride. The bulk layer may include silicon oxide.

The dummy gate electrode 210 (or dummy electrode 210) is formed of polysilicon and is spaced apart from a top surface of a topmost channel layer 208 and sidewalls of the channel layers 208 by the dummy dielectric layer 230. In some embodiments, the dummy dielectric layer 230 includes silicon oxide. The dummy dielectric layer 230 and the dummy electrode 210 may be regarded as a dummy gate stack, which serves a placeholder structure to endure process steps before it is replaced with a metal gate structure. As shown in FIGS. 2 and 4, a dummy gate stack, including the dummy electrode 210 and the dummy dielectric layer 230 may wrap over more than one active regions 204.

The CPODE feature 209 may extend into the substrate 202 and cut a continuous active region into segments and isolate the segments. The CPODE feature 209 may include silicon nitride, silicon oxide, silicon oxynitride, silicon oxycarbonitride, silicon oxycarbide, silicon carbonitride, or a combination thereof. The CPODE feature 209 may include multiple dielectric layers, such as a first dielectric layer 209A and a second dielectric layer 209B as depicted. In some embodiments, the first dielectric layer 209A may include silicon nitride and the second dielectric layer 209B may include silicon oxide. The channel layers 208 connected to a CPODE feature 209 may be referred to as dummy channel layers 208. The CPODE feature 209 may be formed in a CPODE process. In a CPODE process, a dummy gate stack and features therebelow (e.g., portions of the channel layers 208 and the substrate 202) are replaced by a CPODE feature 209. The CPODE features 209 may enhance the circuit performance and improve the pattern density.

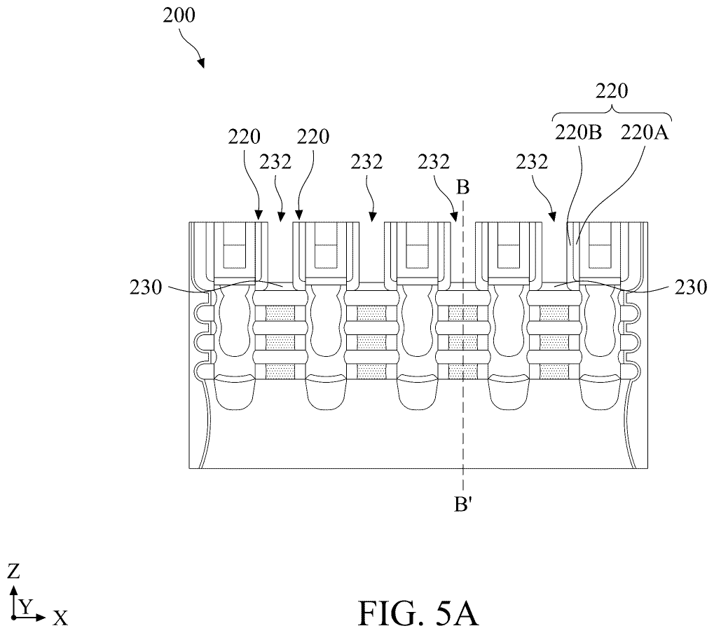

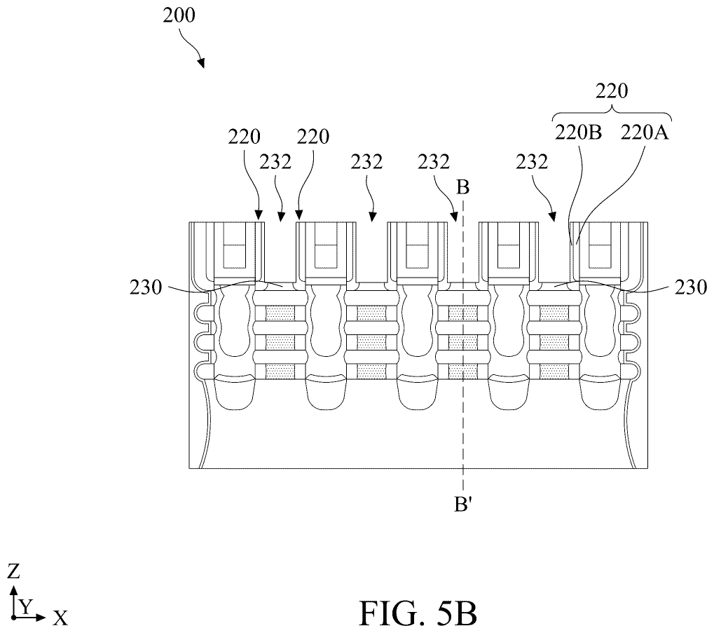

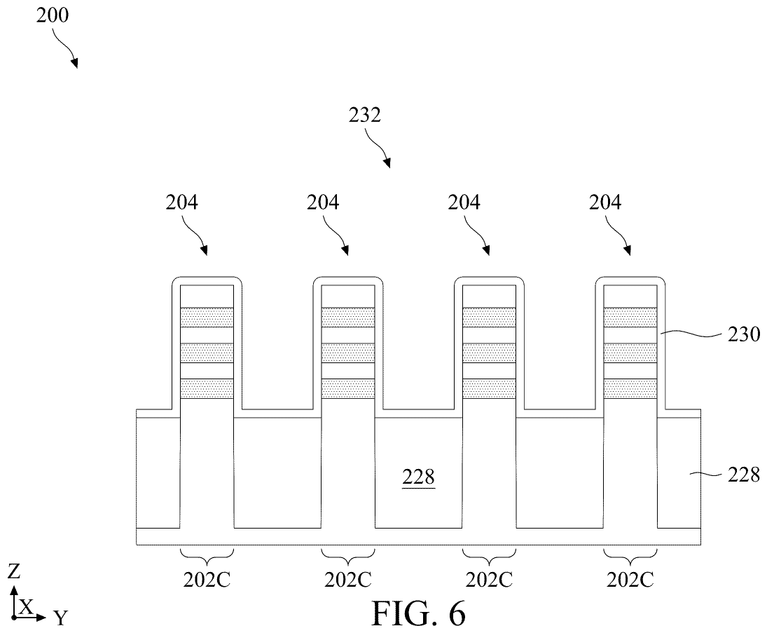

Referring to FIGS. 1, 5A, and 6, method 100 includes a block 104 where the dummy gate electrode 210 are selectively removed to form gate trenches 232. FIG. 6 is a fragmentary cross-sectional view along line B-B′ in FIG. 5A. Referring to FIG. 5A, the removal of the dummy gate electrode 210 may include one or more etching processes that are selective to the material of the dummy gate electrode 210. For example, the removal of the dummy gate electrode 210 may be performed using a selective wet etch, a selective dry etch, or a combination thereof that is selective to the dummy gate electrode 210. In some embodiments, the wet etch at block 104 may include use of a tetramethylammonium hydroxide (TMAH) solution, a potassium hydroxide (KOH) solution, hydrofluoric acid, nitric acid, or a combination thereof. An example dry etch process for block 104 may implement a fluorine-containing gas (e.g., CH2F2, C4F8, C5F8, and/or C2F6), a chlorine-containing gas (e.g., Cl2, CHCl3, CCl4, and/or BCl3), a bromine-containing gas (e.g., HBr and/or CHBr3), an iodine-containing gas, other suitable gases and/or plasmas, and/or combinations thereof. In some embodiments, the dummy dielectric layer 230 may serve as an etch stop layer or help provide etch termination signal at block 104. Referring to FIGS. 5A and 6, the dummy gate electrodes 210 are removed, leaving behind the dummy dielectric layer 230 covering a top surface and sidewalls of the active regions 204 in the channel regions 204C, as well as top surfaces of the isolation features 228. Removal of the dummy gate electrode 210 form gate trenches 232 defined between two gate spacers 220.

Referring to FIGS. 1 and 5B-6, method 100 includes a block 106 where the gate spacers 220 are trimmed to enlarge a width of the gate trenches 232. FIG. 6 is a fragmentary cross-sectional view along line B-B′ in FIG. 5B. Trimming the gate spacers 220 may be performed using a selective wet etch, a selective dry etch, or a combination thereof that is selective to the gate spacers 220. Thicknesses (e.g., in the X direction) of top portions of the gate spacers 220 not covered by the dummy dielectric layer 230 may be reduced. Thicknesses (e.g., in the X direction) of bottom portions of the gate spacers 220 covered by the dummy dielectric layer 230 may remain unchanged. Thus, the gate trenches 232 may be wider for filling of a mask material (to be described). Block 106 is optional. As in FIG. 1, dashed blocks are optional. Although not explicitly shown, it is understood that the gate spacers 220 in the following figures may include the trimmed gate spacers 220 as in FIG. 5B.

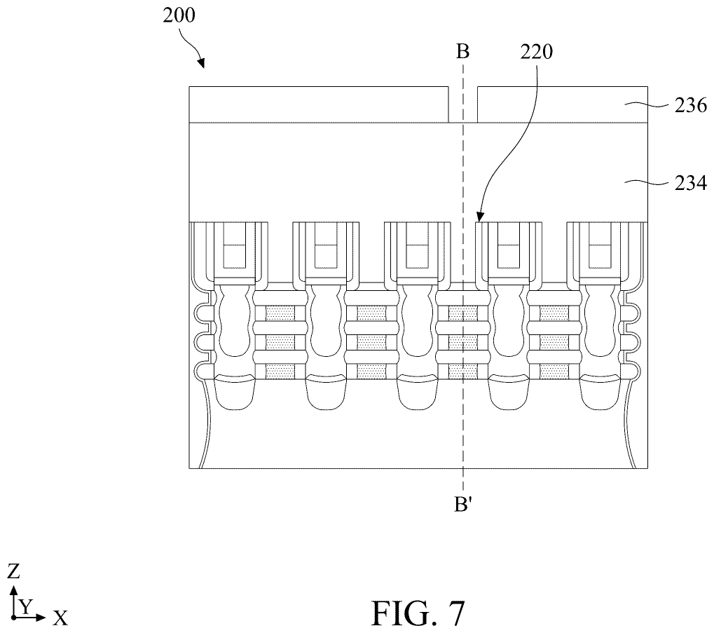

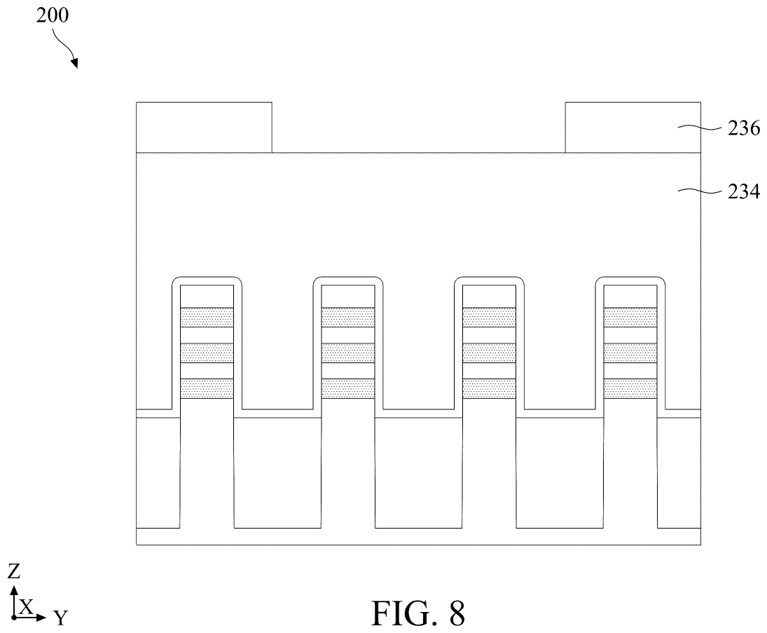

Referring to FIGS. 1 and 7-8, method 100 includes a block 108 where a mask material 234 is formed over the structure 200. FIG. 8 is a fragmentary cross-sectional view along line B-B′ in FIG. 7. In some embodiments, the mask material 234 includes a bottom antireflective coating (BARC) material and provides a platform for photoresist coating and photoresist patterning. The BARC material may include silicon oxynitride (SiON), silicon oxycarbide, a polymer, or other suitable materials. In an embodiment, the mask material 234 is formed by any suitable process, such as CVD, or spin coating a BARC material over the structure 200 and filling the gate trenches 232, and baking the BARC material to cause cross-linking within the BARC material.

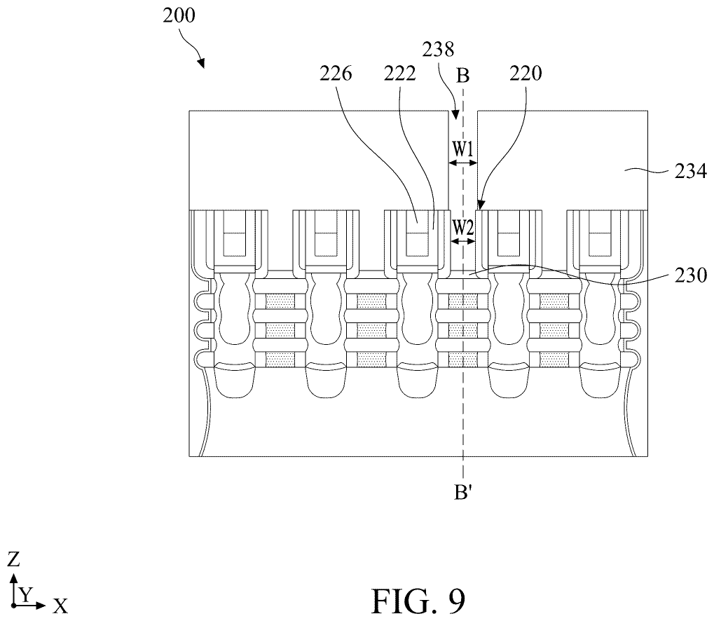

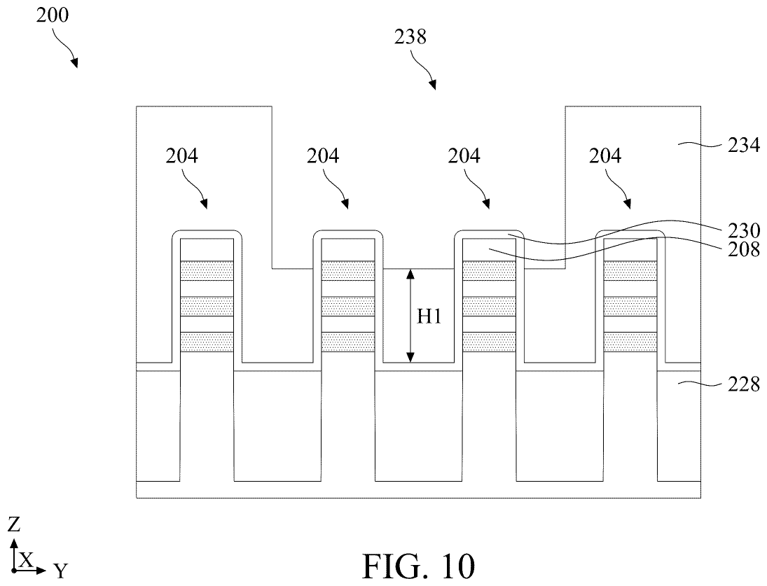

Referring to FIGS. 1 and 7-10, method 100 includes a block 110 where the mask material 234 is patterned to form an opening. FIG. 10 is a fragmentary cross-sectional view along line B-B′ in FIG. 9. Operations at block 110 may include forming a patterned photoresist layer 236 over the mask material 234 (FIGS. 7-8), and etching the mask material 234 using the patterned photoresist layer 236 as an etch mask (FIGS. 9-10). Referring to FIGS. 7-8, after forming the mask material 234, a patterned photoresist layer 236 is formed over the mask material 234. In an example process, a photoresist layer may be blanketly deposited over the structure 200, including over the mask material 234. The photoresist layer is then exposed to radiation going through or reflected from a mask, baked in a post-bake process, and developed in a developer solution to form the patterned photoresist layer 236, as represented in FIGS. 7-8. In this illustrated embodiment, the patterned photoresist layer 236 is formed to have an opening. In some embodiments, the opening is directly above at least a portion of one of the gate trenches 232 in FIGS. 5-6.

Referring to FIGS. 9-10, an etching process is then performed to recess the mask material 234 while using the patterned photoresist layer 236 as an etch mask. The etching process may include an anisotropic etching process. The etching process may include use of a dry etch process. The dry etch process may include use of plasma of argon (Ar), oxygen (O2), nitrogen (N2), hydrogen (H2), or a combination thereof. After removing at least a top portion of the mask material 234 from the area not covered by the patterned photoresist layer 236, the patterned photoresist layer 236 may be selectively removed. Upon completion of operations at block 110, an opening 238 is formed in the mask material 234 and/or between the gate spacers 220. In some embodiments, the opening 238 exposes a region (also referred to as a low power region or a low capacitance region) where capacitance of the device(s) is to be reduced. In the depicted embodiment, the opening 238 includes a portion (e.g., over two active regions 204 in the middle in FIG. 10) of one of the gate trenches 232 (i.e., the third gate trench 232 from left in FIG. 9). In some embodiments, a topmost surface of the dummy dielectric layer 230 is exposed in the opening 238. In some embodiments, inside the opening 238, a top surface of the mask material 234 is coplanar or below the topmost surface of the dummy dielectric layer 230. The depth of the opening 238 may be flexible, thus increasing process window of forming the opening 238 and increasing product yield. A height H1 of the mask material 234 below the opening 238 may be 0 to about 40 nm. When H1 is 0, the mask material 234 in the area not covered by the patterned photoresist layer 236 is all removed, and the dummy dielectric layer 230 on a top surface of the isolation feature 228 is exposed in the opening 238. Referring to FIG. 9, the opening 238 may have a width W1 between opposing sidewalls of the mask material 234 and a width W2 between opposing sidewalls of the gate spacers 220. In some embodiments, W1 is equal to or greater than W2. A ratio of W1 to W2 may increase, as the etching selectivity between the gate spacers 220 and the dummy dielectric layer 230 (or the channel layer 208) in following processes (e.g., blocks 112 and 114, to be described) increases. The etching selectivity between the gate spacers 220 and the dummy dielectric layer 230 is defined as a ratio of an etching rate of the dummy dielectric layer 230 to an etching rate of the gate spacers 220. In some embodiments where the etching selectivity is S1, the opposing sidewalls of the mask material 234 intersect with top surfaces of the gate spacers 220. In some embodiments where the etching selectivity is S2 and greater than S1, the opposing sidewalls of the mask material 234 may intersect with top surfaces of the CESL 222 or the dielectric cap layer 226. In some cases, the patterned photoresist layer 236 may be removed during or after the etching process.

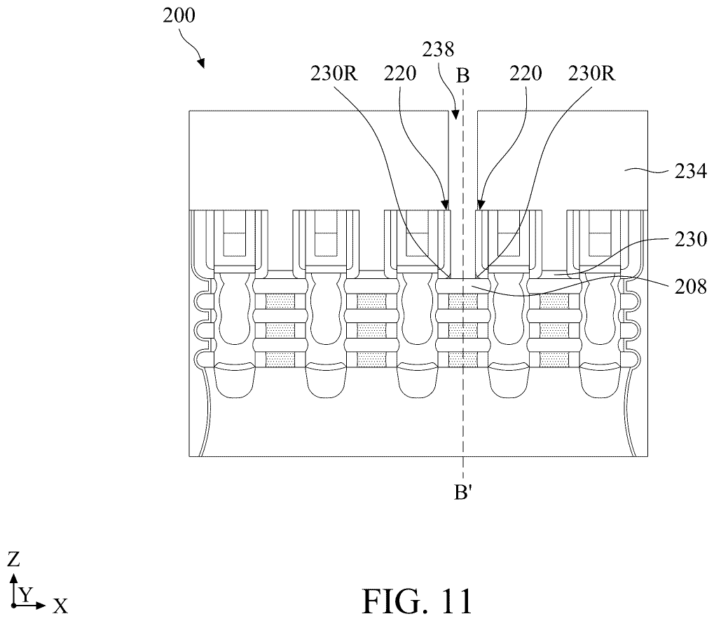

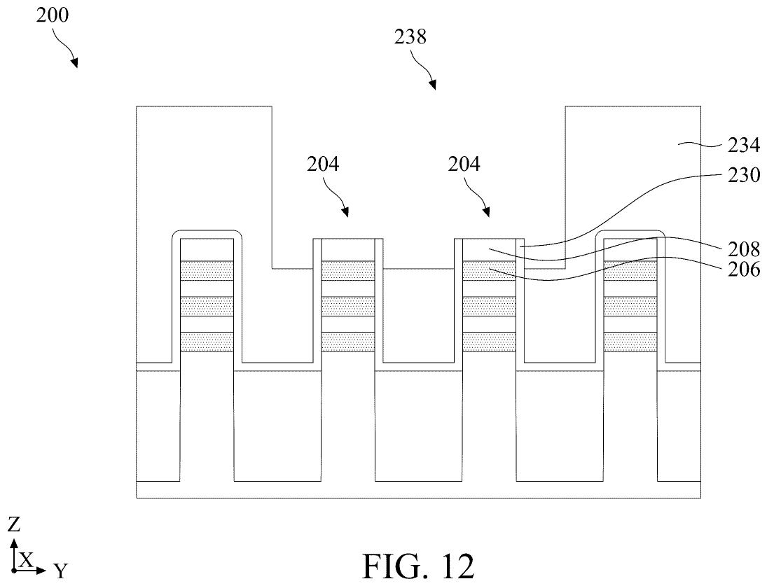

Referring to FIGS. 1 and 11-12, method 100 includes a block 112 where a first etching process is performed to remove a top portion of the dummy dielectric layer 230 to expose a topmost channel layer 208. FIG. 12 is a fragmentary cross-sectional view along line B-B′ in FIG. 11. In some embodiments, the first etching process is highly selective to the dummy dielectric layer 230. The first etching process may include an anisotropic etching. In some embodiments, the first etching process includes a dry etch process that implements oxygen (O2), hydrogen (H2), argon (Ar), ammonia (NH3), a fluorine-carbon gas (e.g., anhydrous hydrogen fluoride (HF) vapor, trifluoromethane (CHF3), nitrogen trifluoride (NF3), carbon tetrafluoride (CF4), sulfur hexafluoride (SF6), or a combination thereof. As illustrated in FIG. 11, in some embodiments, because the first etching process is anisotropic, a residue portion 230R of the dummy dielectric layer 230 may remain directly below the gate spacers 220. As shown in FIG. 11, because the first etching process is directional, sidewalls of the residue portion 230R of the dummy dielectric layer 230 are substantially aligned with the sidewalls of the gate spacers 220 thereabove and are substantially flat. In some embodiments, the sidewalls of the residue portion 230R of the dummy dielectric layer 230 are substantially vertical. In some other embodiments, before the first etching process, no dummy dielectric layer 230 is sandwiched between bottom surfaces of the gate spacers 220 and the top surface of the topmost channel layer 208, thus no residue portion 230R is left therebetween after the first etching process. The topmost channel layer 208 may serve as an etch stop layer or help provide etch termination signal at block 112. The dummy dielectric layer 230 on sidewalls of the channel layers 208 and the interposers 206 may remain as shown in FIG. 12. Upon completion of the first etching process, a middle portion of the topmost channel layer 208 is exposed in the opening 238. A top surface of the dummy dielectric layer 230 and the top surface of the topmost channel layer 208 exposed in the opening 238 may be coplanar.

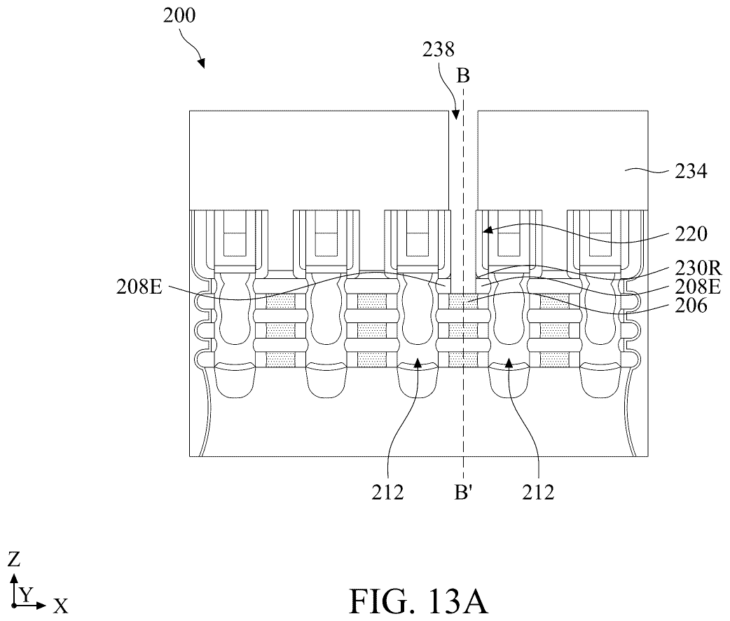

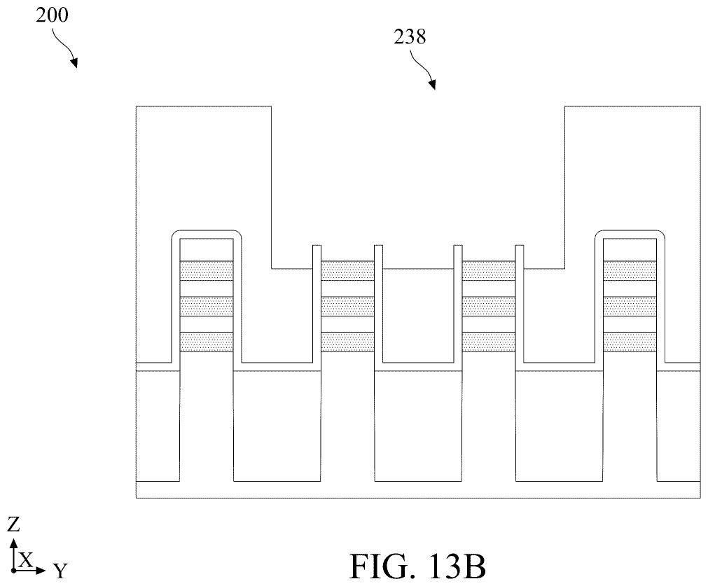

Referring to FIGS. 1 and 13A-13B, method 100 includes a block 114 where a second etching process is performed to selectively remove the middle portion of the topmost channel layer 208. FIG. 13B is a fragmentary cross-sectional view along line B-B′ in FIG. 13A. After operations at block 112 expose the topmost channel layers 208 in the opening 238, a dry etch is performed to etch through the topmost channel layers 208 to extend the opening 238. In some embodiments, because a composition of the dummy gate electrode 210 and a composition of the channel layers 208 are similar, the dry etch process at block 114 may be similar to the dry etch process at block 104. The second etching process may include an anisotropic etching. In some embodiments, the second etching process includes a dry etch process that implements oxygen (O2). The topmost interposer 206 may serve as an etch stop layer or help provide etch termination signal at block 114. Upon completion of the second etching process, the middle portion of the topmost channel layer 208 is removed, and two end portions 208E of the topmost channel layer 208 remain underlying the gate spacers 220 and the residue portion 230R of the dummy dielectric layer 230. As shown in FIG. 13A, because the second etching process is directional, sidewalls of the two end portions 208E of the topmost channel layer 208 are substantially aligned with the sidewalls of the residue portion 230R of the dummy dielectric layer 230 and the sidewalls of the gate spacers 220 thereabove and are substantially flat. In some embodiments, the sidewalls of the two end portions 208E are substantially vertical. The two end portions 208E may prevent the source/drain features 212 from being damaged in the etching process. The channel layers 208 below the two end portions 208E remain as full channel layers 208 (e.g., the channel layers 208 extending between two source/drain features 212, with the middle portions not removed). Because the dry etch at block 114 etches the topmost channel layers 208 faster than it etches the dummy dielectric layer 230 or the interposers 206, the etching of the topmost channel layers 208 may leave the dummy dielectric layer 230 protruding above a top surface of the topmost interposers 206. A top surface of the dummy dielectric layer 230 in the opening 238 may be at a similar level as in FIG. 12.

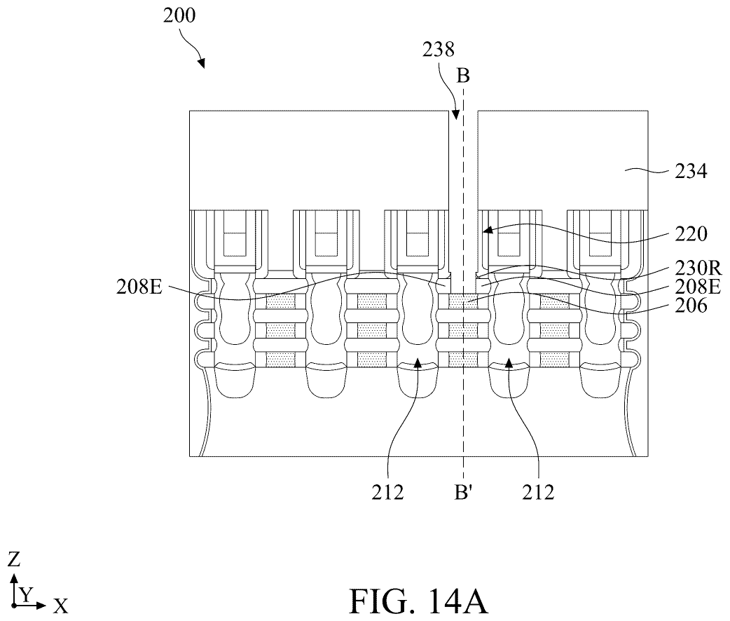

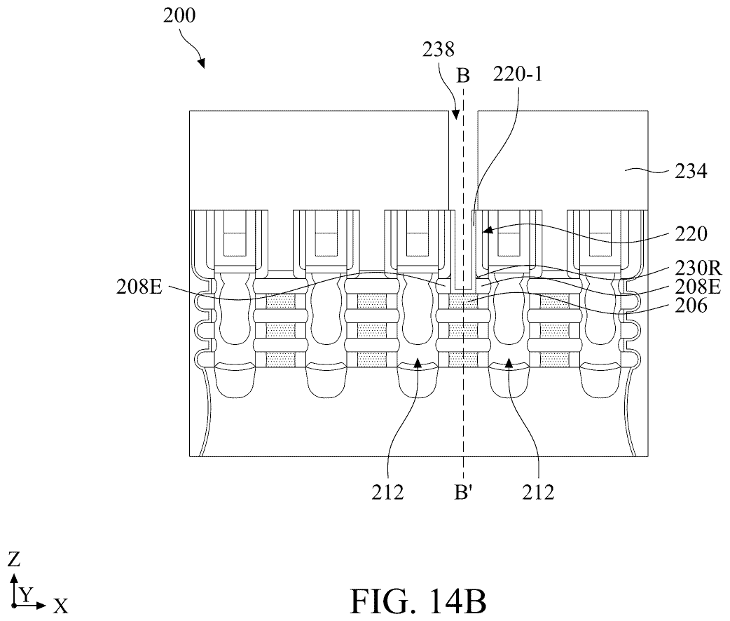

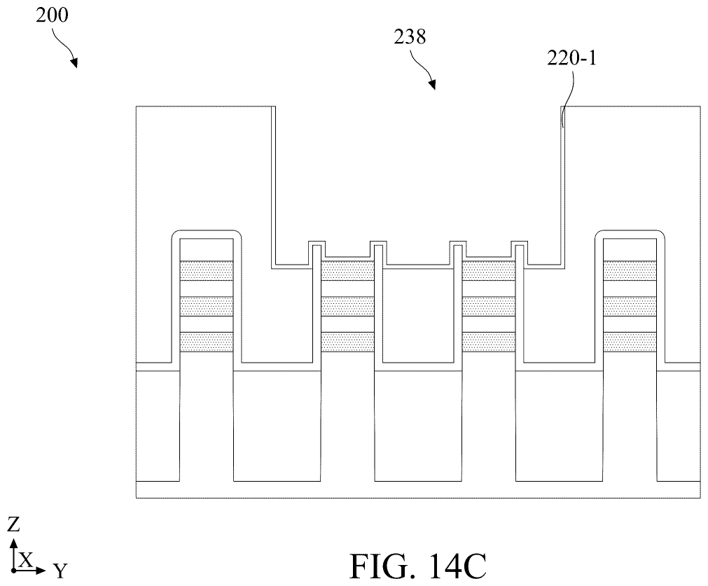

Referring to FIGS. 1 and 14A, method 100 includes a block 120 where the gate spacers 220 are trimmed to enlarge the width between the opposing sidewalls of the gate spacers 220 in the opening 238. Trimming the gate spacers 220 may be performed using a selective wet etch, a selective dry etch, or a combination thereof that is selective to the gate spacers 220. Thicknesses of the gate spacers 220 (e.g., in the X direction) may be reduced. Thus, the opening 238 may provide wider access for following processes. Block 120 is optional. In some embodiments, referring to FIGS. 14B-14C, before trimming the gate spacers, operations at block 120 include depositing a thin spacer layer 220-1 including materials of the gate spacers 220 on the sidewalls and the bottom surface of the opening 238. FIG. 14C is a fragmentary cross-sectional view along line B-B′ in FIG. 14B. The thin spacer layer 220-1 may have a thickness of less than about 3 nm. The thin spacer layer 220-1 may protect the exposed end portions 208E, and may be removed during the trimming process. Although not explicitly shown, it is understood that the gate spacers 220 in the following figures may include the trimmed gate spacers 220 as in FIG. 14A.

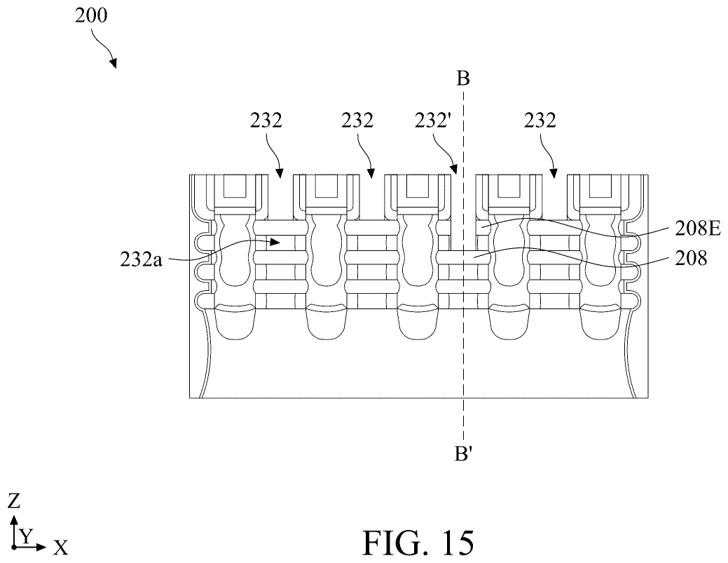

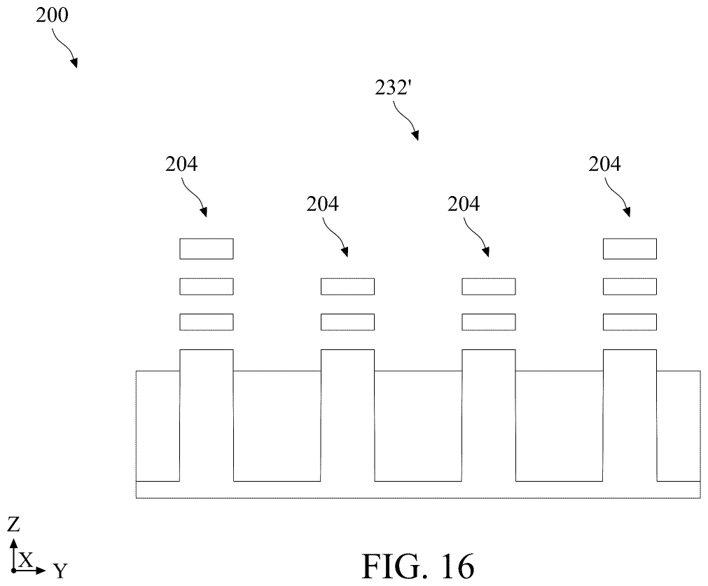

Referring to FIGS. 1 and 15-16, method 100 includes a block 122 where the channel layers 208 are released. FIG. 16 is a fragmentary cross-sectional view along line B-B′ in FIG. 15. Operations at block 122 include selectively removing remaining portions of the mask material 234, the dummy dielectric layer 230, and the interposers 206.

One or more etching processes may be performed to remove the remaining portion of the mask material 234 without substantially etching other features (e.g., the channel layers 208, the base fin 208B, the gate spacers 220). The mask material 234 may be removed using an ashing process or a dry etch process that includes use of plasma of argon (Ar), oxygen (O2), nitrogen (N2), hydrogen (H2), or a combination thereof. After removing the mask material 234, the gate trenches 232 and enlarged gate trenches 232′ are released. Because of operations at blocks 106 and/or 120, the enlarged gate trench 232′ may have greater width in the X direction than the gate trenches 232. Because of the removal of the topmost channel layer 208 at block 114, the enlarged gate trench 232′ exposes the sidewalls of the end portions 208E.

At block 122, a separate etch process may be performed to selectively remove the dummy dielectric layer 230 including the residue portion 230R. For example, a selective wet etch process or a selective dry etch process may be performed to remove the dummy dielectric layer 230. An example selective wet etch process may include use of diluted hydrofluoric acid (DHF) or a mixture of hydrofluoric acid (HF) and, ammonium fluoride (NH4F). An example selective dry etch process may include use of anhydrous hydrogen fluoride (HF) vapor, trifluoromethane (CHF3), nitrogen trifluoride (NF3), hydrogen (H2), ammonia (NH3), carbon tetrafluoride (CF4), sulfur hexafluoride (SF6), or a combination thereof.

After removing the dummy dielectric layer 230, sidewalls of the interposers 206 are exposed. The interposers 206 are selectively removed to form spaces 232a between adjacent channel layers 208 as extended portions of the gate trenches 232. In some embodiments, the interposers 206 include an oxide as described above and may be removed in a same etch process or a following similar etch process as the removal of the dummy dielectric layer 230. In some other embodiments, the interposers 206 include a semiconductor material (e.g., SiGe, GeSn) as described above. In such embodiments, after removing the dummy dielectric layer 230, a selective etching process is performed to remove the interposers 206. The selective removal of the interposers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). In the depicted embodiment as in FIG. 16, the two active regions 204 in the middle have fewer channel layers in the stack compared to the active regions 204 on the left and right sides.

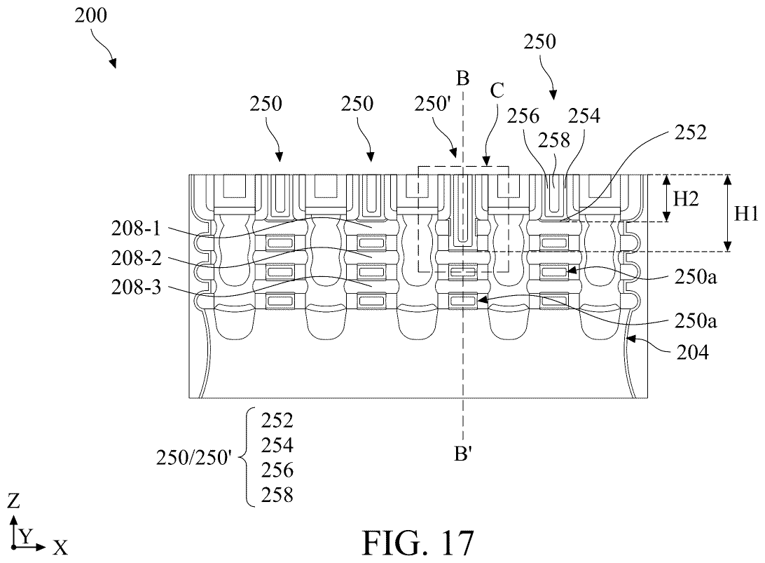

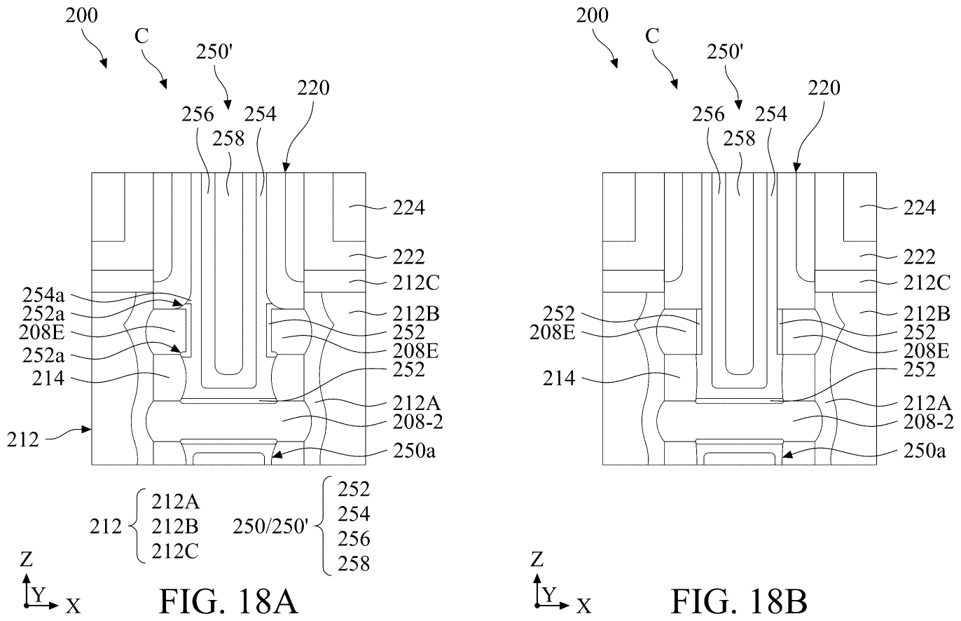

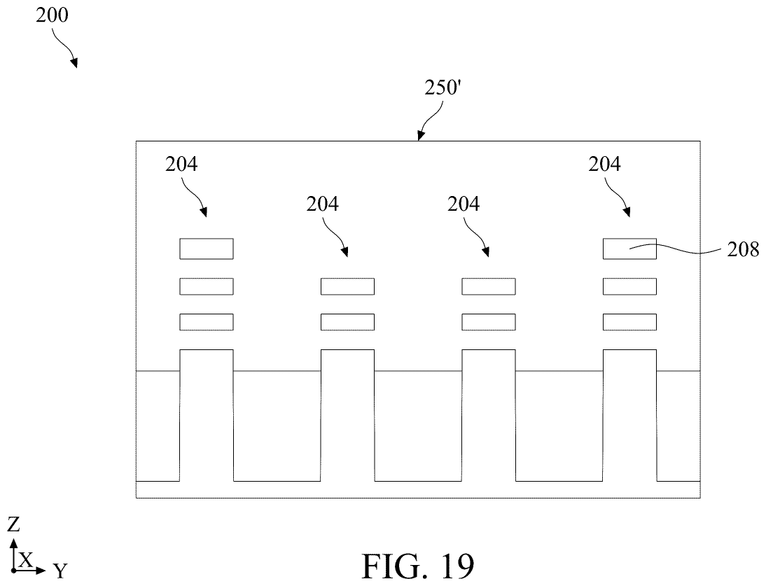

Referring to FIGS. 1 and 17-19, method 100 includes a block 124 where gate structures 250 and 250′ are formed to wrap around the channel layers 208. The gate structures 250 and 250′ are formed in the gate trenches 232 and 232′ as in FIG. 15, respectively. FIG. 18A illustrates an enlarged view of a portion C of the structure 200 as in FIG. 17. FIG. 18B illustrates an alternative enlarged view of the portion C as in FIG. 17. FIG. 19 is a fragmentary cross-sectional view along line B-B′ in FIG. 17.

After the release of the channel layers 208, the gate structure 250/250′ is formed to wrap around each of the full channel layers 208. The gate structure 250/250′ includes an interfacial layer 252 interfacing the channel layers 208, the end portions 208E, and the base fin 208B in the channel region 204C, a gate dielectric layer 254 over the interfacial layer 252, and a gate electrode layer over the gate dielectric layer 254. The interfacial layer 252 may include a dielectric material such as silicon oxide, hafnium silicate, or silicon oxynitride. The interfacial layer 252 may be formed by chemical oxidation, thermal oxidation, atomic layer deposition (ALD), chemical vapor deposition (CVD), and/or other suitable method. The gate dielectric layer 254 may include a high-k dielectric material, such as hafnium oxide. Alternatively, the gate dielectric layer 254 may include other high-K dielectric materials, such as titanium oxide (TiO2), hafnium zirconium oxide (HfZrO), tantalum oxide (Ta2O5), hafnium silicon oxide (HfSiO4), zirconium oxide (ZrO2), zirconium silicon oxide (ZrSiO2), lanthanum oxide (La2O3), aluminum oxide (Al2O3), zirconium oxide (ZrO), yttrium oxide (Y2O3), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. In some embodiments, a thickness of the gate dielectric layer 254 is less than a thickness of the gate spacer 220. The gate dielectric layer 254 may be formed by ALD, physical vapor deposition (PVD), CVD, oxidation, and/or other suitable methods.

The gate electrode layer includes a work function metal layer 256 and a metal fill layer 258 over the work function layer 256. The work function metal layer 256 is a p-type work function metal layer in the p-type transistors or an n-type work function metal layer in the n-type transistors. The p-type work function metal layer includes a metal selected from, but not limited to, the group of titanium nitride, tantalum nitride, ruthenium, molybdenum, tungsten, platinum, or combinations thereof. The n-type work function metal layer includes a material selected from, but not limited to, the group of titanium, aluminum, tantalum carbide, tantalum carbide nitride, tantalum silicon nitride, or combinations thereof. In some embodiments, the p-type or n-type work function metal layer includes a plurality of layers deposited by CVD, PVD, and/or other suitable process. The metal fill layer 258 includes aluminum, tungsten, cobalt, copper, and/or other suitable materials, and is formed by CVD, PVD, plating, and/or other suitable processes. In various embodiments, a CMP process may be performed to remove excessive metal, thereby providing a substantially planar top surface of the gate structures 250/250′.

For clarity, the channel layers 208 from top to bottom in the active region 204 may be referred to as a channel layer 208-1 (or a topmost channel layer 208-1), a channel layer 208-2 (or a second-from-top channel layer 208-2), etc., which can be collectively or individually referred to as channel layer(s) 208 depending on the context. Both the gate structures 250 and 250′ include an interlayer portion 250a and a top portion over the interlayer portions 250a. The interlayer portion 250a may be disposed between two channel layers 208 or between a bottommost channel layer 208 and the substrate 202. The top portion extends upward from the topmost channel layer 208-1 for the gate structure 250 and from the channel layer 208-2 for the gate structure 250′. In the depicted embodiments in FIG. 17, the gate structure 250′ wraps around two channel layers 208 and the gate structure 250 wraps around three channel layers 208. Because the gate structure 250′ wraps around one less channel layer 208, a first height H1 of the top portion of the gate structure 250′ is greater than a second height H2 of the top portion of the gate structure 250. In some instances, the first height H1 is greater than the second height H2 by a difference between about 10 nm and about 30 nm. This difference is substantially equal to a sum of a thickness of the channel layer 208 and a spacing between two neighboring channel layers 208. In the depicted embodiments in FIG. 19, the gate structure 250′ wraps around two channel layers 208 of the two active regions 204 in the middle, and wraps around three channel layers 208 of the two active regions 204 on the left and right sides.

In some embodiments, after removing the remaining portion of the dummy dielectric 230 and the interposers 206, portions of the top and bottom surfaces of the end portions 208E of the topmost channel layers 208 are exposed. Thus, referring to FIG. 18A, in the gate structure 250′, the interfacial layer 252 includes a vertical portion on the sidewall of the end portions 208E and tip portions 252a formed on the exposed portions of the top and bottom surfaces of the end portions 208E. In some embodiments, the gate dielectric layer 254 may include protruding portions 254a over the tip portions 252a and a U-shaped portion extending along the sidewalls of the gate spacers 220, the vertical portions of the interfacial layer 252, and the inner spacers 214, and the top surface of the second-from-top channel layer 208. The tip portion 252a and the corresponding protruding portion 254a above the end portion 208E may be disposed between the gate spacer 220 and the end portion 208E. In some embodiments, the sidewalls of the inner spacers 214 curve away from the adjacent source/drain features 212. In some embodiments, the sidewalls of the gate spacers 220 and the end portions 208E are laterally beyond the sidewalls of the inner spacers 214. The tip portion 252a and the corresponding protruding portion 254a below the end portion 208E may be disposed between the inner spacer 214 and the end portion 208E. In some alternative embodiments, referring to FIG. 18B, the top and/or bottom surfaces of the end portions 208E are not exposed after the channel release and before forming the gate structures 250/250′. In such embodiments, the interfacial dielectric layer 252 on the end portions 208E includes the vertical portion and no or a portion of the tip portions 252a (in FIG. 18A). The gate dielectric layer 254 includes the U-shaped portion and no or a portion of the protruding portions 254a (in FIG. 18A).

The semiconductor device 200 may undergo further processing to form various features and regions known in the art. For example, subsequent processing may form additional interlayer dielectric (ILD) layer(s), contacts/vias/lines and multilayers interconnect features (e.g., metal layers and interlayer dielectrics) over the substrate 202, configured to connect the various features to form a functional circuit that may include one or more devices including the semiconductor device 200. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure.

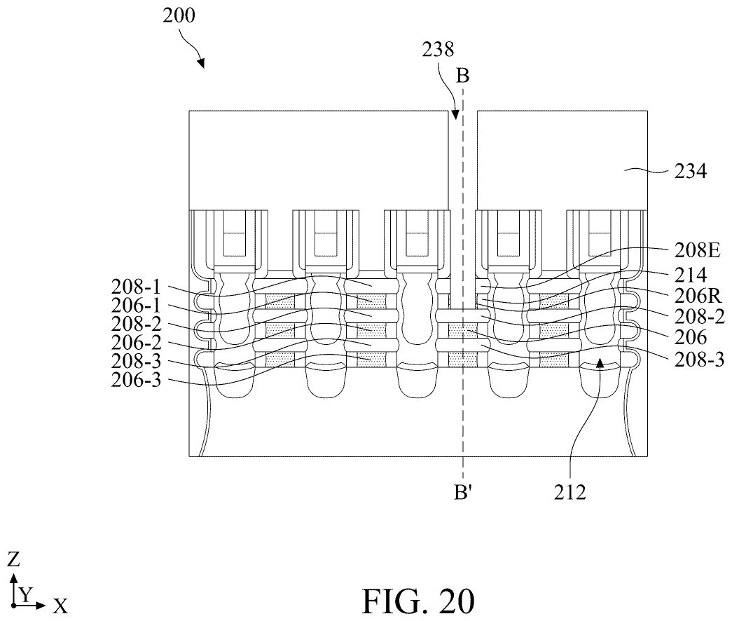

Reducing middle portions of one or more of the top channel layers may reduce capacitance of the device. In FIGS. 17-19, the middle portion of the topmost channel layer 208-1 may be removed, while the other channel layers 208 (e.g., channel layers 208-2, 208-3) remain as full channel layers 208, thus reducing capacitance of the device formed by the gate structure 250′ and the active region 204 having less channel layers 208. In some embodiments, middle portions of additional channel layer(s) 208 (e.g., 208-2) may be removed to further reduce the number of full channel layer(s) 208 in the active region 204, thus further reducing capacitance of the device. FIGS. 20-27 illustrate some embodiments where middle portions of the second-from-top channel layer 208-2 are removed.

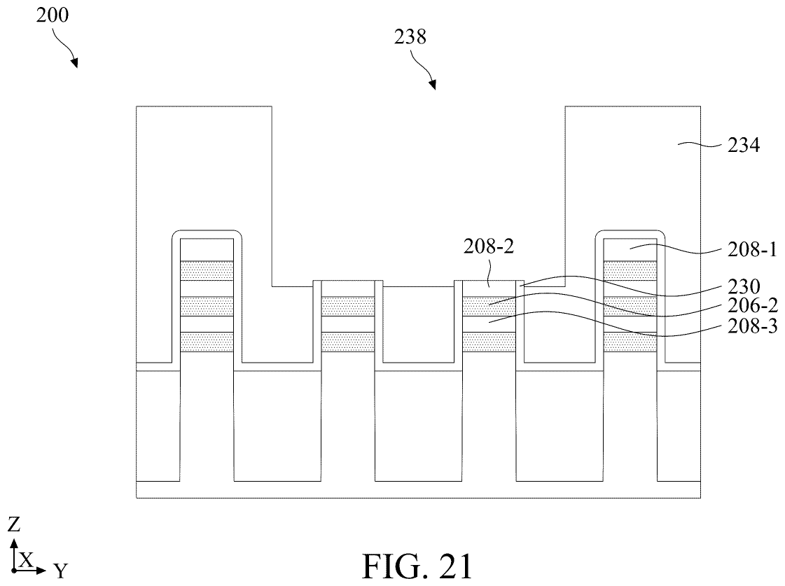

Referring to FIGS. 1 and 20-21, after block 114 as in FIGS. 13-14, method 100 may include an optional block 116 where an additional etching process is formed to remove an interposer 206 (e.g., a topmost interposer 206) exposed in the opening 238. FIG. 21 is a fragmentary cross-sectional view along line B-B′ in FIG. 20. For clarity, the interposers 206 from top to bottom in an active region 204 may be referred to as an interposer 206-1 (or a topmost interposer 206-1), an interposer 206-2 (or a second-from-top interposer 206-2), etc., which can be collectively or individually referred to as interposer(s) 206 depending on the context. In the depicted embodiments in FIGS. 13-14, upon completion of the second etching process, the topmost interposer 206 is exposed. In some embodiments, the interposers 206 include the oxide as described above. In such embodiments, the additional etching process includes an anisotropic etching process similar to the first etching process at block 112 to selectively remove the exposed interposer 206. As illustrated in FIG. 20, in some embodiments, the additional etching process is anisotropic, and the sidewalls of the gate spacers 220 and the end portions 208E are laterally beyond sidewalls of the inner spacers 214. Thus, a residue portion 206R of the topmost interposer 206 may remain directly below the end portions 208E after the additional etching process. In some embodiments, the sidewalls of the inner spacers 214 curve away from the adjacent source/drain feature 212. In some other embodiments, the sidewalls of the inner spacers are beyond or align with the sidewalls of the gate spacers 220 and the end portions 208E, and no residue portion 206R is formed. The channel layer 208 therebelow (e.g., the second-from-top channel layer 208-2) may serve as an etch stop layer or help provide etch termination signal at block 116. Referring to FIGS. 14 and 21, the dummy dielectric layer 230 may be etched in the additional etching process. The dummy dielectric layer 230 on sidewalls of the channel layer 208-2 and therebelow may remain. The top surface of the dummy dielectric layer 230 may be coplanar as the channel layer 208-2. Upon completion of the additional etching process, a middle portion of the channel layer 208-2 may be exposed in the opening 238.

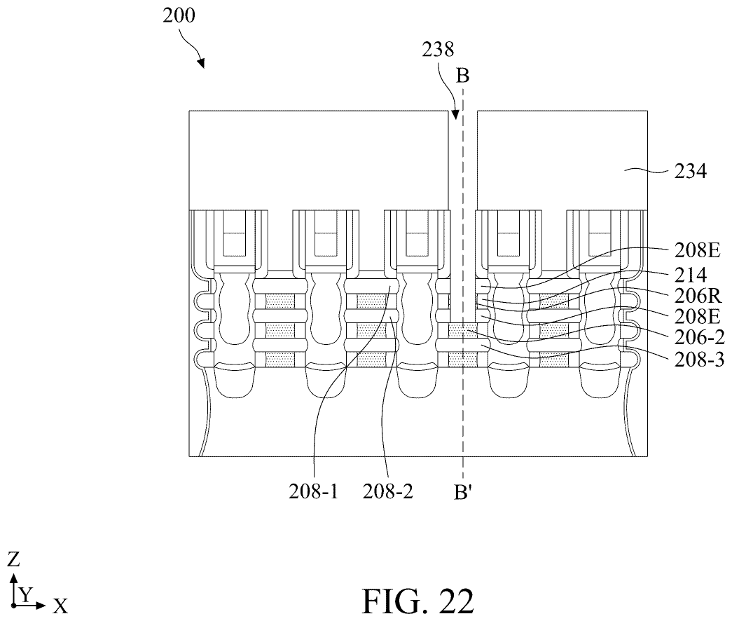

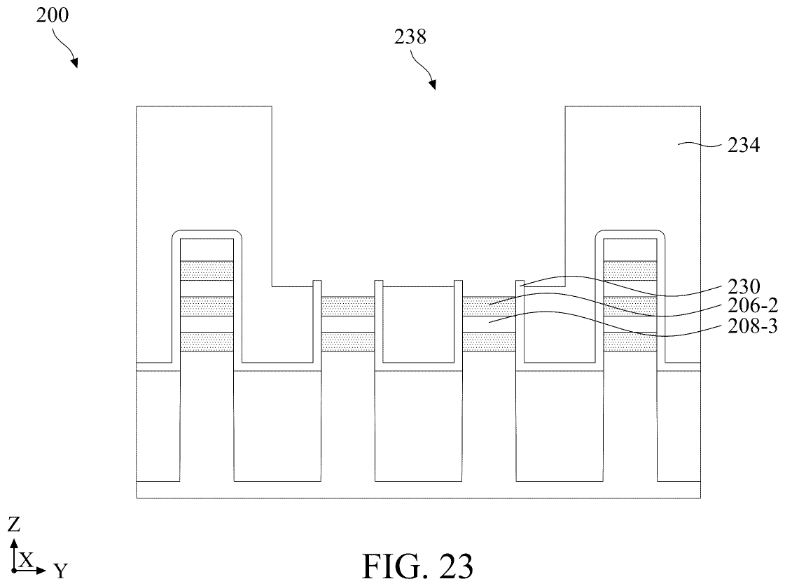

Referring to FIGS. 1 and 22-23, method 100 may include an optional block 118 where an additional etching process is formed to remove the middle portion of a channel layer 208 (e.g., 208-2) exposed in the opening 238. FIG. 23 is a fragmentary cross-sectional view along line B-B′ in FIG. 22. In some embodiments, the additional etching process includes an anisotropic etching process similar to the second etching process at block 114 to selectively remove a middle portion of the exposed channel layer 208. The interposer 206 therebelow (e.g., the second-from-top interposer 206) may serve as an etch stop layer or help provide etch termination signal at block 118. In the depicted embodiment, upon completion of the additional etching process, the middle portion of the channel layer 208-2 is removed, and two end portions of the channel layer 208-2 remain under the inner spacers 214 and the residue portions 206R of the interposer 206. As shown in FIG. 22, because the etching processes at blocks 116 and 118 are directional, sidewalls of the residue portions 206R of the interposer 206 and the two end portions 208E of the channel layer 208-2 are substantially flat (e.g., vertical). The sidewalls of the residue portions 206R of the interposer 206 and the two end portions 208E of the channel layer 208-2 may align with the sidewalls of the gate spacers 220 and the two end portions 208E of the channel layer 208-1. Because the dry etch at block 118 etches the channel layers 208-2 faster than it etches the dummy dielectric layer 230 or the interposers 206, the etching of the channel layers 208-2 may leave the dummy dielectric layer 230 protruding above a top surface of the interposers 206-2, such as shown in FIG. 23.

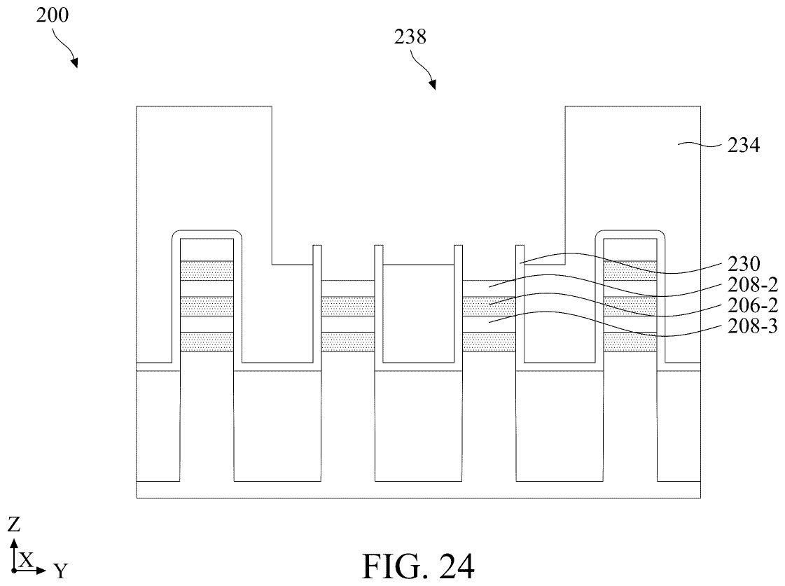

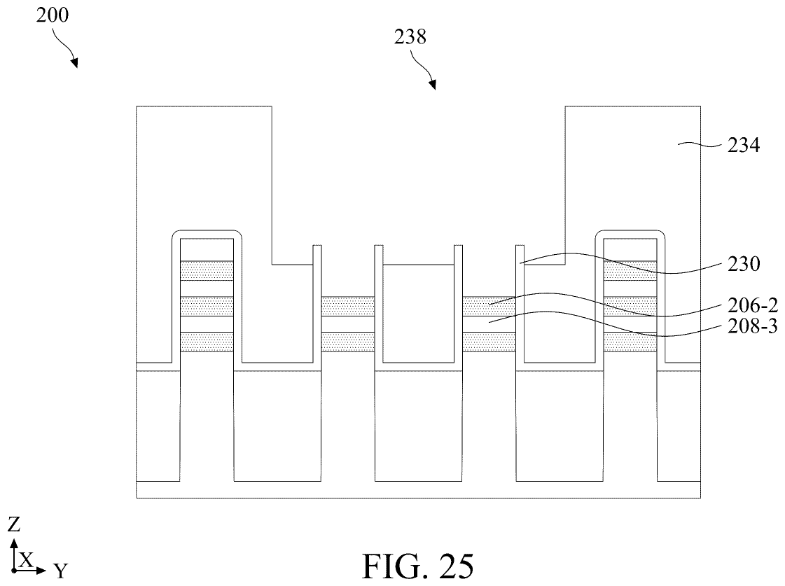

Referring to FIGS. 20, 22, and 24-25, in some alternative embodiments, the interposers 206 include a semiconductor material (e.g., SiGe, GeSn) as described above. FIGS. 24 and 25 are fragmentary cross-sectional views along line B-B′ in FIGS. 20 and 22, respectively. In such embodiments, referring to FIGS. 20 and 24, the additional etching process at block 116 includes an anisotropic etching process (e.g., selective dry etch, selective wet etch, or other selective etch processes) to selectively remove the exposed interposer 206-1. An example selective dry etching process may include use of one or more fluorine-based etchants, such as fluorine gas or hydrofluorocarbons. In some embodiments, the dummy dielectric layer 230 is etched at a slower rate than the topmost interposer 206-1 during the etching process at block 116. After removing the topmost interposer 206-1, the dummy dielectric layer 230 may protrude above a top surface of the channel layer 208-2. A top surface of the dummy dielectric layer 230 in the opening 238 may be at a similar level as in FIG. 12 or FIG. 14.

Referring to FIGS. 22 and 25, the additional etching process at block 118 includes an anisotropic etching process similar as described above to selectively remove the middle portion of a channel layer 208 (e.g., 208-2) exposed in the opening 238. After removing the channel layer 208, the dummy dielectric layer 230 may protrude above a top surface of the interposer 206-2. A top surface of the dummy dielectric layer 230 in the opening 238 may be at a similar level as in FIG. 12 or FIG. 14.

Operations at blocks 116 and 118 may be repeated to remove more channel layer(s) 208. At least one full channel layer 208 may remain in a semiconductor layer stack in an active region 204. After middle portion(s) of designed number of channel layer(s) 208 is removed, the structure 200 may proceed to block 120 or block 122 as described above. In some embodiments, blocks 116 and 118 are omitted.

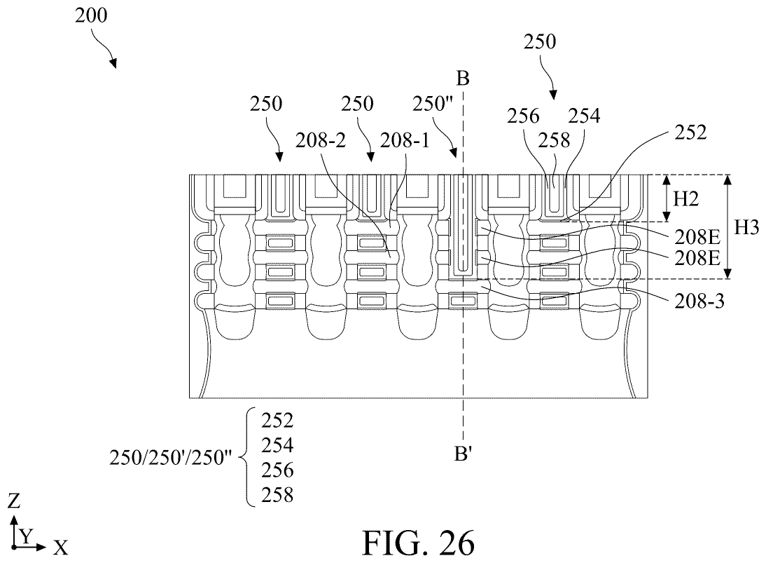

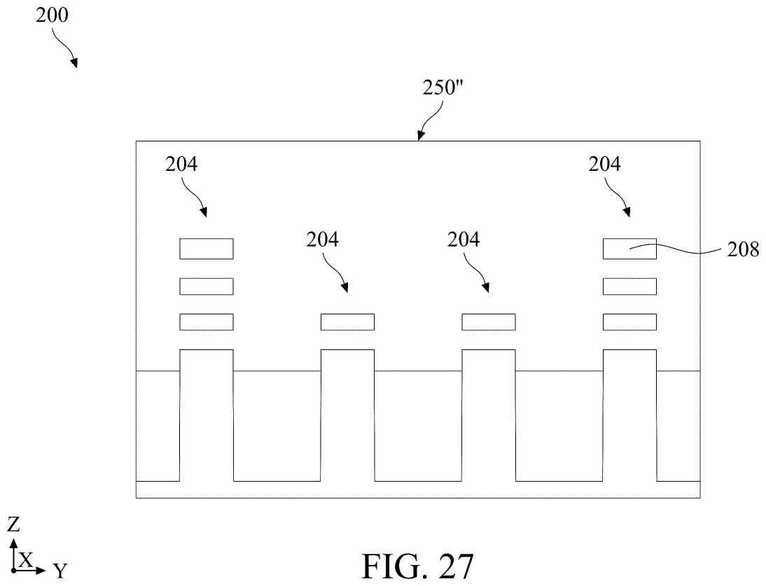

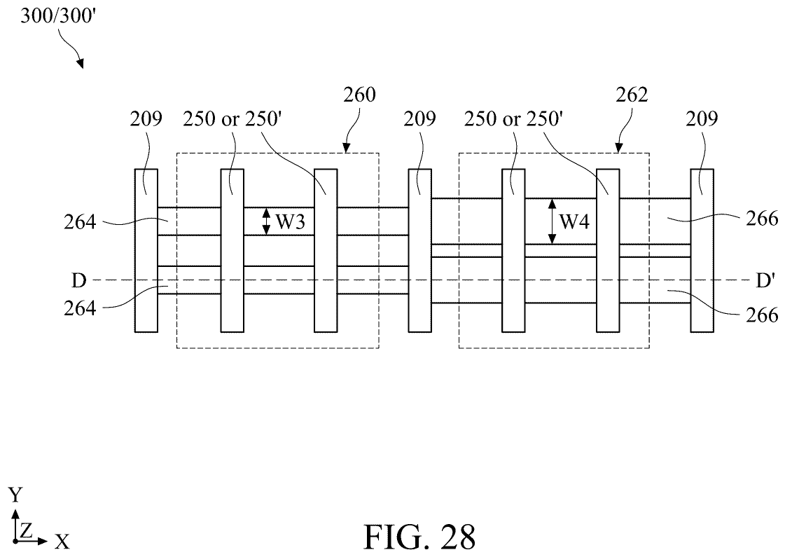

Referring to FIGS. 1 and 26-27, at block 124, the gate structures 250 and 250″ are formed similarly as described above to the gate structures 250 and 250′. FIG. 27 is a fragmentary cross-sectional view along line B-B′ in FIG. 26. In the depicted embodiment in FIG. 26, the gate structure 250″ wraps around the channel layer 208-3, and extends between the end portions 208E of the channel layer 208-1 and between the end portions 208E of the channel layer 208-2. The interfacial layer 252 and the gate dielectric layer 254 on the end portions 208E of the channel layer 208-2 may have similar profiles as described above on the end portions 208E of the channel layer 208-1. In some embodiments, the interfacial layer 252 includes tip portions, and the gate dielectric layer 254 includes protruding portions adjacent to the top and bottom surfaces of the end portions 208E of the channel layer 208-2. The tip portions and the protruding portions may be similar to those described in FIG. 18A. In some other embodiments, similar to the embodiments in FIG. 18B, the interfacial layer 252 does not include tip portions, and the gate dielectric layer 254 does not include corresponding protruding portions. Differences from the gate structure 250′ include that the top portion of the gate structure 250″ extends upward from the channel layer 208-3. In the depicted embodiment in FIG. 26, the gate structure 250″ wraps around one channel layer 208 and the gate structure 250 wraps around three channel layers 208. Because the gate structure 250″ wraps around two less channel layers 208, a third height H3 of the top portion of the gate structure 250″ is greater than the second height H2 of the top portion of the gate structure 250. In some instances, the third height H3 is greater than the second height H2 by a difference between about 20 nm and about 60 nm. This difference is substantially equal to a sum of thicknesses of two channel layers 208 (e.g., 208-1 and 208-2) and two times of the spacing between two neighboring channel layers 208.

The removal of the top channel layer(s) 208 (e.g., the channel layer 208-1, or the channel layers 208-1 and 208-2) substantially reduces the device capacitance. Channel widths may also affect device capacitance. In general, a smaller channel width may lead to reduced capacitance and a greater channel width may lead to increased capacitance. The removal of the top channel layer(s) described above may be implemented to active regions with different widths. FIGS. 28-32 illustrate some examples.

Referring to FIG. 28, in some embodiments, a structure 300 or an alternative structure 300′ may include a first region 260 and a second region 262. The first region 260 includes first active regions 264 having a smaller first channel width W3. The second region 262 includes second active regions 266 having a greater second channel width W4. W3 and W4 may be in the Y direction. In some embodiments, a ratio of W4 to W3 is between about 1.1 and about 2.0. Each of the first active regions 264 and the second active regions 266 extend lengthwise along the X direction. In the depicted embodiment, each of the first active regions 264 is aligned with a second active region 266 along the X direction. In the depicted embodiments, the first active regions 264 and the second active regions 266 are isolated by a CPODE feature 209 as described above. The first region 260 and the second region 262 may be adjacent to (e.g., as in FIG. 28) or separated from each other.

FIG. 29 illustrates a fragmentary cross-sectional view of the structure 300 taken along line D-D′ as in FIG. 28. In some embodiments, referring to FIGS. 28 and 29, in the structure 300, the gate structures 250′ (similarly shown in FIGS. 17-19) are implemented over the first active regions 264, and the gate structures 250 (similarly shown in FIG. 17) are implemented over the second active regions 266. In some embodiments not depicted, instead of the gate structures 250′, more than one top channel layer 208 of the first active regions 264 are removed. For example, the gate structures 250″ (similarly shown in FIGS. 26-27) are implemented over the first active regions 264, where two top channel layers 208-1 and 208-2 are removed. In some embodiments, because the first region 260 has less channel layers 208 in the first active regions 264 and narrower active regions, the first region 260 has a lower device capacitance than the second region 262. Thus, the first region 260 of the structure 300 may be referred to as a low power circuit region, a low speed region, or a low capacitance region. The second region 262 of the structure 300 may be referred to as a high power circuit region, a high speed region, or a high capacitance region. FIG. 30 illustrates a fragmentary cross-sectional view of the alternative structure 300′ taken along line D-D′ as in FIG. 28. In some embodiments, referring to FIGS. 28 and 30, in the alternative structure 300′, the gate structures 250′ (similarly shown in FIGS. 17-19) are implemented over the second active regions 266 and the gate structures 250 (similarly shown in FIG. 17) are implemented over the first active regions 264. In some embodiments not depicted, instead of the gate structures 250′, more than one top channel layer 208 of the active regions 266 are removed. For example, the gate structures 250″ (similarly shown in FIGS. 26-27) are implemented over the second active regions 266, where two top channel layers 208-1 and 208-2 are removed.

Referring to FIG. 31, in some embodiments, a structure 400 may include a first region 268, a second region 270, and a third region 272. The first region 268 includes first active regions 274, the second region 270 includes second active regions 276, and the third region 272 includes third active regions 278. Each of the first active regions 274, the second active regions 276, and the third active regions 278 extend lengthwise along the X direction. In the depicted embodiment, each of the first active regions 274 is aligned with a second active region 276 and a third active region 278 along the X direction. In the depicted embodiment, the first active regions 274, the second active regions 276, and the third active regions 278 have the same width in the Y direction. In some embodiments, a continuous active region is formed and then cut by CPODE features 209 to form the first region 268, the second region 270, and the third region 272. In some alternative embodiments, the active regions 274, the second active regions 276, and the third active regions 278 have different widths in the Y direction. In the depicted embodiments, the first active regions 274 and the second active regions 276 are isolated by a CPODE feature 209 as described above, the second active regions 276 and the third active regions 278 are isolated by another CPODE feature 209 as described above. The first region 268, the second region 270, and the third region 272 may be adjacent to (e.g., as in FIG. 31) or separated from each other. FIG. 31 is merely an example and is not intended to limit the arrangement of the first region 268, the second region 270, and the third region 272.

FIG. 32 illustrates a fragmentary cross-sectional view of the structure 400 taken along line E-E′ as in FIG. 31. In some embodiments, referring to FIGS. 31 and 32, the gate structures 250′ (similarly shown in FIGS. 17-19) are implemented over the first active regions 274, the gate structures 250 (similarly shown in FIG. 17) are implemented over the second active regions 276, and the gate structures 250'′ (similarly shown in FIGS. 26-27) are implemented over the third active regions 278. In some embodiments, the active regions in the first region 268, the second region 270, and the third region 272 have the same width and different numbers of channel layers 208. Thus, in the depicted embodiment, the first region 268 has a higher capacitance than the third region 272, and the second region 270 has a higher capacitance than the first region 268. Thus, the first region 268 may be referred to as a low power circuit region, a low speed region, or a low capacitance region. The second region 270 may be referred to as a high power circuit region, a high speed region, or a high capacitance region. The third region 272 may be referred to as a super low power circuit region, a super low speed region, or a super low capacitance region.

Although not intended to be limiting, one or more embodiments of the present disclosure provide many benefits to a semiconductor structure. For example, the present disclosure provides more flexibility in tuning capacitance of semiconductor devices. For example, by removing a middle portion of one or more top channel layer after removing the dummy gate structure, capacitance of the semiconductor device may be reduced, while subsequent processes are not impacted. By removing different numbers of channel layers in different device regions of a semiconductor structure, device regions having different capacitance may be achieved. Thus, the overall performance of the semiconductor structure may be improved.

In one exemplary aspect, the present disclosure is directed to a method. The method includes providing a structure including a first stack of alternating first channel layers and first interposer layers, a second stack of alternating second channel layers and second interposer layers, an epitaxial feature disposed between the first stack and the second stack, a first dummy gate electrode over the first stack, and a second dummy gate electrode over the second stack. The epitaxial feature is doped with a dopant, the epitaxial feature includes a first layer and a second layer, a concentration of the dopant in the first layer varies from a concentration of the dopant in the second layer. The method further includes removing the first dummy gate electrode and the second dummy gate electrode, thereby forming a first gate trench and a second gate trench, respectively, forming a mask layer in the first gate trench and the second gate trench, removing a portion of the mask layer from the first gate trench, performing an anisotropic etch process in the first gate trench to remove a portion of a topmost first channel layer, removing a remaining portion of the mask layer from the first gate trench and the second gate trench, removing the first interposer layers and the second interposer layers, forming a first metal gate structure in the first gate trench and wrapping around lower first channel layers below the topmost first channel layer, and forming a second metal gate structure in the second gate trench and wrapping around the second channel layers.

In some embodiments, the structure further includes an oxide layer over the first stack, the first dummy gate electrode is over the oxide layer, removing the portion of the mask layer from the first gate trench exposes the oxide layer, the anisotropic etch process is a first anisotropic etch process, before performing the first anisotropic etch process, the method further includes performing a second anisotropic etch process to remove a top portion of the oxide layer. In some embodiments, after removing the remaining portion of the mask layer, the method further includes removing a remaining portion of the oxide layer. In some embodiments, the structure further includes gate spacers disposed on a first sidewall of the first dummy gate electrode and a second sidewall of the second dummy gate electrode, removing the portion of the mask layer from the first gate trench exposes the first sidewall and the second sidewall, and after performing the second anisotropic etch process, a residue of the oxide layer remains below the gate spacers and above the topmost first channel layer. In some embodiments, the first interposer layers include an oxide or a semiconductor material, the semiconductor material has a different composition from the first channel layers and the second channel layers. In some embodiments, after performing the anisotropic etch process, the topmost first channel layer includes two end portions, the two end portions have vertical sidewalls, the first metal gate structure interfaces with the vertical sidewalls. In some embodiments, the structure further includes gate spacers disposed on a first sidewall of the first dummy gate electrode and a second sidewall of the second dummy gate electrode, before forming the mask layer and after removing the first dummy gate electrode and the second dummy gate electrode, the method further includes trimming the gate spacers to reduce thicknesses of the gate spacers. In some embodiments, after performing the anisotropic etch process, further including trimming the gate spacers to further reduce the thicknesses of the gate spacers.

In another exemplary aspect, the present disclosure is directed to a method. The method includes providing a structure including a stack of alternating channel layers and interposer layers, an oxide layer over the stack, a dummy gate electrode over the oxide layer, a source/drain feature connected to a sidewall of the stack, a contact etch stop layer (CESL) extending along a top surface of the source/drain feature, and an interlayer dielectric (ILD) layer over the CESL. A thickness of the CESL is less than a thickness of the ILD layer. The method further includes removing the dummy gate electrode to form a gate opening, forming a mask layer in the gate opening and over the CESL and the ILD layer, patterning the mask layer to remove the mask layer from the gate opening, performing a first etch process to remove a top portion of the oxide layer using the mask layer as an etch mask, performing a second etch process to remove a portion of a topmost channel layer, removing a remaining portion of the mask layer, removing the interposer layers and a remaining portion of the oxide layer, thereby enlarging the gate opening, and forming a metal gate structure in the gate opening and wrapping around lower channel layers below the topmost channel layer.

In some embodiments, performing the second etch process exposes a top surface of a topmost interposer layer. In some embodiments, the interposer layers include an oxide or a semiconductor material, the semiconductor material has a different composition from the channel layers. In some embodiments, the structure further includes a gate spacer layer disposed along a sidewall of the dummy gate electrode, after performing the first etch process, a residue of the oxide layer remains between the gate spacer layer and the topmost channel layer. In some embodiments, the first etch process includes an anisotropic etch process. In some embodiments, the second etch process includes a selective anisotropic process, before performing the second etch process, the oxide layer includes a side portion disposed on sidewalls of the portion of the topmost channel layer, after performing the second etch process, the side portion of the oxide layer remains. In some embodiments, after performing the second etch process and before removing the remaining portion of the mask layer, further including removing a topmost interposer and a portion of a second-from-top channel layer. In some embodiments, after performing the second etch process, the topmost channel layer includes two separated remaining portions having opposing sidewalls, forming the metal gate structure includes forming interfacial layers on the opposing sidewalls.

In yet another exemplary aspect, the present disclosure is directed to a semiconductor structure. The semiconductor structure includes a stack of first channel layers, a second channel layer on a side and apart from the stack of first channel layers, a first gate structure disposed over and wrapping around the stack of first channel layers, the first gate structure including a first top portion above a topmost first channel layer, a second gate structure disposed over and wrapping around the second channel layer, the second gate structure including a second top portion directly above the second channel layer and extending continuously to a level of a top surface of the first top portion, and a source/drain feature connected to the stack of first channel layers and the second channel layer. A bottom surface of the first top portion is higher than a bottom surface of the second top portion, the source/drain feature is doped with a dopant, the source/drain feature includes a first layer and a second layer, a concentration of the dopant in the first layer varies from a concentration of the dopant in the second layer.

In some embodiments, the semiconductor structure further includes a first and a second semiconductor layers disposed over the second channel layer, and gate spacers disposed on sidewalls of the second gate structure and on top surfaces of the first and the second semiconductor layers. In some embodiments, the second gate structure includes interfacial layers disposed on opposing sidewalls of the first and the second semiconductor layers. In some embodiments, the opposing sidewalls of the first and the second semiconductor layers are vertical, and the interfacial layers are further disposed on top and bottom surfaces of the first and the second semiconductor layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a structure comprising:
a first stack of alternating first channel layers and first interposer layers,
a second stack of alternating second channel layers and second interposer layers,
an epitaxial feature disposed between the first stack and the second stack, wherein the epitaxial feature is doped with a dopant, wherein the epitaxial feature comprises a first layer and a second layer, wherein a concentration of the dopant in the first layer varies from a concentration of the dopant in the second layer,
a first dummy gate electrode over the first stack, and
a second dummy gate electrode over the second stack;
removing the first dummy gate electrode and the second dummy gate electrode, thereby forming a first gate trench and a second gate trench, respectively;
forming a mask layer in the first gate trench and the second gate trench;
removing a portion of the mask layer from the first gate trench;
performing an anisotropic etch process in the first gate trench to remove a portion of a topmost first channel layer;
removing a remaining portion of the mask layer from the first gate trench and the second gate trench;
removing the first interposer layers and the second interposer layers;
forming a first metal gate structure in the first gate trench and wrapping around lower first channel layers below the topmost first channel layer; and
forming a second metal gate structure in the second gate trench and wrapping around the second channel layers.

2. The method of claim 1, wherein the structure further comprises an oxide layer over the first stack,
wherein the first dummy gate electrode is over the oxide layer,
wherein removing the portion of the mask layer from the first gate trench exposes the oxide layer,
wherein the anisotropic etch process is a first anisotropic etch process,
wherein before performing the first anisotropic etch process, the method further comprises performing a second anisotropic etch process to remove a top portion of the oxide layer.

3. The method of claim 2, after removing the remaining portion of the mask layer, further comprising removing a remaining portion of the oxide layer.

4. The method of claim 2, wherein the structure further comprises gate spacers disposed on a first sidewall of the first dummy gate electrode and a second sidewall of the second dummy gate electrode,
wherein removing the portion of the mask layer from the first gate trench exposes the first sidewall and the second sidewall, and
wherein after performing the second anisotropic etch process, a residue of the oxide layer remains below the gate spacers and above the topmost first channel layer.

5. The method of claim 1, wherein the first interposer layers comprise an oxide or a semiconductor material,
wherein the semiconductor material has a different composition from the first channel layers and the second channel layers.

6. The method of claim 1, wherein after performing the anisotropic etch process, the topmost first channel layer comprises two end portions,
wherein the two end portions have vertical sidewalls,
wherein the first metal gate structure interfaces with the vertical sidewalls.

7. The method of claim 1, wherein the structure further comprises gate spacers disposed on a first sidewall of the first dummy gate electrode and a second sidewall of the second dummy gate electrode,
wherein before forming the mask layer and after removing the first dummy gate electrode and the second dummy gate electrode, the method further comprises trimming the gate spacers to reduce thicknesses of the gate spacers.

8. The method of claim 7, after performing the anisotropic etch process, further comprising trimming the gate spacers to further reduce the thicknesses of the gate spacers.

9. A method, comprising:
providing a structure comprising:
a stack of alternating channel layers and interposer layers,
an oxide layer over the stack,
a dummy gate electrode over the oxide layer,
a source/drain feature connected to a sidewall of the stack,
a contact etch stop layer (CESL) extending along a top surface of the source/drain feature, and
an interlayer dielectric (ILD) layer over the CESL, wherein a thickness of the CESL is less than a thickness of the ILD layer;
removing the dummy gate electrode to form a gate opening;
forming a mask layer in the gate opening and over the CESL and the ILD layer;
patterning the mask layer to remove the mask layer from the gate opening;
performing a first etch process to remove a top portion of the oxide layer using the mask layer as an etch mask;
performing a second etch process to remove a portion of a topmost channel layer;
removing a remaining portion of the mask layer;
removing the interposer layers and a remaining portion of the oxide layer, thereby enlarging the gate opening; and
forming a metal gate structure in the gate opening and wrapping around lower channel layers below the topmost channel layer.

10. The method of claim 9, wherein performing the second etch process exposes a top surface of a topmost interposer layer.

11. The method of claim 9, wherein the interposer layers comprise an oxide or a semiconductor material,
wherein the semiconductor material has a different composition from the channel layers.

12. The method of claim 9, wherein the structure further comprises a gate spacer layer disposed along a sidewall of the dummy gate electrode,
wherein after performing the first etch process, a residue of the oxide layer remains between the gate spacer layer and the topmost channel layer.

13. The method of claim 9, wherein the first etch process comprises an anisotropic etch process.

14. The method of claim 9, wherein the second etch process comprises a selective anisotropic process,
wherein before performing the second etch process, the oxide layer comprises a side portion disposed on sidewalls of the portion of the topmost channel layer,
wherein after performing the second etch process, the side portion of the oxide layer remains.

15. The method of claim 9, after performing the second etch process and before removing the remaining portion of the mask layer, further comprising removing a topmost interposer and a portion of a second-from-top channel layer.

16. The method of claim 9, wherein after performing the second etch process, the topmost channel layer comprises two separated remaining portions having opposing sidewalls,
wherein forming the metal gate structure comprises forming interfacial layers on the opposing sidewalls.

17. A semiconductor structure, comprising:
a stack of first channel layers;
a second channel layer on a side and apart from the stack of first channel layers;
a first gate structure disposed over and wrapping around the stack of first channel layers, the first gate structure comprising a first top portion above a topmost first channel layer;
a second gate structure disposed over and wrapping around the second channel layer, the second gate structure comprising a second top portion directly above the second channel layer and extending continuously to a level of a top surface of the first top portion; and
a source/drain feature connected to the stack of first channel layers and the second channel layer,
wherein a bottom surface of the first top portion is higher than a bottom surface of the second top portion, wherein the source/drain feature is doped with a dopant, wherein the source/drain feature comprises a first layer and a second layer, wherein a concentration of the dopant in the first layer varies from a concentration of the dopant in the second layer.

18. The semiconductor structure of claim 17, further comprising:
a first and a second semiconductor layers disposed over the second channel layer; and
gate spacers disposed on sidewalls of the second gate structure and on top surfaces of the first and the second semiconductor layers.

19. The semiconductor structure of claim 18, wherein the second gate structure comprises interfacial layers disposed on opposing sidewalls of the first and the second semiconductor layers.

20. The semiconductor structure of claim 19, wherein the opposing sidewalls of the first and the second semiconductor layers are vertical, and
wherein the interfacial layers are further disposed on top and bottom surfaces of the first and the second semiconductor layers.
